(19) United States
(12) Patent Application Publication
(10) Pub. No.: US 2026/0068255 A1
(43) Pub. Date: Mar. 5, 2026

(54) SEMICONDUCTOR STRUCTURE WITH SIDEWALL-FREE DIPOLE METAL FEATURE AND METHOD FOR MANUFACTURING THE SAME

(71) Applicant: TAIWAN SEMICONDUCTOR MANUFACTURING COMPANY, LTD., Hsinchu (TW)

(72) Inventors: Hsin WANG, Hsinchu (TW); Olivia Pei-Hua LEE, Hsinchu (TW); Chia-Hung CHU, Hsinchu (TW); Po-Chin CHANG, Hsinchu (TW); Sung-Li WANG, Hsinchu (TW); Wei-Yip LOH, Hsinchu (TW); Hao-Chin HUANG, Hsinchu (TW); Chun-Yuan CHEN, Hsinchu (TW); Yun Ju FAN, Hsinchu (TW)

(73) Assignee: TAIWAN SEMICONDUCTOR MANUFACTURING COMPANY, LTD., Hsinchu (TW)

(21) Appl. No.: 18/823,023

(22) Filed: Sep. 3, 2024

(51) Int. Cl. H01L 21/285; H01L 29/06; H01L 29/417; H01L 29/423; H01L 29/45; H01L 29/66; H01L 29/775; H01L 29/786

(52) U.S. Cl. CPC H01L 21/28518; H10D 30/014; H10D 30/43; H10D 30/6729; H10D 30/6735; H10D 30/6757; H10D 62/121; H10D 64/017; H10D 64/018; H10D 64/62

(57) ABSTRACT

A method for forming a semiconductor structure includes: forming a trench in a base structure; forming a dipole metal layer in the trench, the dipole metal layer having a lateral portion formed along a sidewall of the trench and a bottom portion formed along a bottom wall of the trench; removing the lateral portion of the dipole metal layer using an etchant including at least one of a metal halide and a hydrogen halide; after removal of the lateral portion of the dipole metal layer, forming a metal silicide layer over the bottom portion of the dipole metal layer using a precursor including the metal halide; and forming a metal contact in the trench.

### BACKGROUND

In a field effect transistor (FET), metal contacts (known as MD metal) are configured to be electrically connected to source/drain portions thereof. It is important to develop novel techniques in manufacturing of FETs so that the metal contacts of FETs thus manufactured have low contact resistance, thereby improving device performance.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1 is a flow diagram illustrating a method for manufacturing a semiconductor structure in accordance with some embodiments.

FIGS. 2 to 21 are schematic views illustrating intermediate stages of the method for manufacturing the semiconductor structure in accordance with some embodiments as depicted in FIG. 17.

FIG. 22 is a flow diagram illustrating a method for manufacturing metal contacts depicted in FIG. 21 in accordance with some embodiments.

FIGS. 23 to 34 are schematic views illustrating intermediate stages of the method for manufacturing the metal contacts in accordance with some embodiments as depicted in FIG. 22.

FIGS. 35 to 37 are graphs illustrating variation in thickness and etching rate of metal samples that are respectively formed on different materials.

### DETAILED DESCRIPTION

The following disclosure provides many different embodiments, or examples, for implementing different features of the disclosure. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “on,” “above,” “top,” “bottom,” “bottommost,” “upper,” “uppermost,” “lower,” “lowermost,” “over,” “beneath,” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

For the purposes of this specification and appended claims, unless otherwise indicated, all numbers expressing amounts, sizes, dimensions, proportions, shapes, formulations, parameters, percentages, quantities, characteristics, or other numerical values used in the specification and claims, are to be understood as being modified in all instances by the term “about” even if the term “about” is not explicitly recited with the values, amounts or ranges. Accordingly, unless otherwise indicated, the numerical parameters set forth in the following specification and appended claims are not and need not be exact, but may be approximations and/or larger or smaller than specified as desired, may encompass tolerances, conversion factors, rounding off, measurement error, and other factors known to those of skill in the art depending on the desired properties sought to be obtained by the presently disclosed subject matter. For example, the term “about,” when used with a value, can capture variations of, in some aspects ±10%, in some aspects ±5%, in some aspects ±2.5%, in some aspects ±1%, in some aspects ±0.5%, and in some aspects ±0.1% from the specified amount, as such variations are appropriate to perform the disclosed methods or employ the disclosed compositions.

Source/drain portion(s) may refer to a source or a drain, individually or collectively dependent upon the context.

The present disclosure is directed to a semiconductor structure including a device having a source/drain portion, a dielectric feature disposed on the source/drain portion, a metal contact penetrating the dielectric feature, a dipole metal feature disposed between the metal contact and the source/drain portion, and a metal silicide feature. The metal silicide feature is disposed around the metal contact. In addition, the metal silicide feature has a vertical portion and a horizontal portion. The vertical portion is sandwiched between the metal contact and the dielectric feature. The horizontal portion is sandwiched between the metal contact and the dipole metal feature. In some embodiments, the device is an n-type device. In other embodiments, the device is a p-type device. In an exemplary embodiment provided in the following description, the device is a gate-all-around (GAA) field effect transistor (FET), but is not limited thereto. In some embodiments, the device may be other nanosheet FET, such as forksheet FET, complementary FET, or the likes. In other embodiments, the device may be a planar transistor, a fin-type FET, or the likes. Other suitable devices and applications are within the contemplated scope of the present disclosure. A method for making the semiconductor structure is also disclosed. In some embodiments, the method includes forming a dipole metal layer in a trench which is bordered by the source/drain portion at the bottom of the trench and the dielectric feature at the sidewall of the trench. An etching process is performed to mainly remove a lateral portion of the dipole metal layer so as to allow a larger capacity (of the trench) to be filled with the metal contact (and the metal silicide feature), thereby allowing the metal contact to have a low resistance (Rc). In the etching process, the etchant employed may be a metal halide and/or a hydrogen halide. It is noted that the metal halide may also serve as a precursor for forming the metal silicide feature. That is, both the etching process and formation of the metal silicide feature make use of a same chemical reagent, and can be performed in an in-situ manner, so as to reduce damage of other elements of the semiconductor structure, to reduce contamination, and to have a simple and fast work flow.

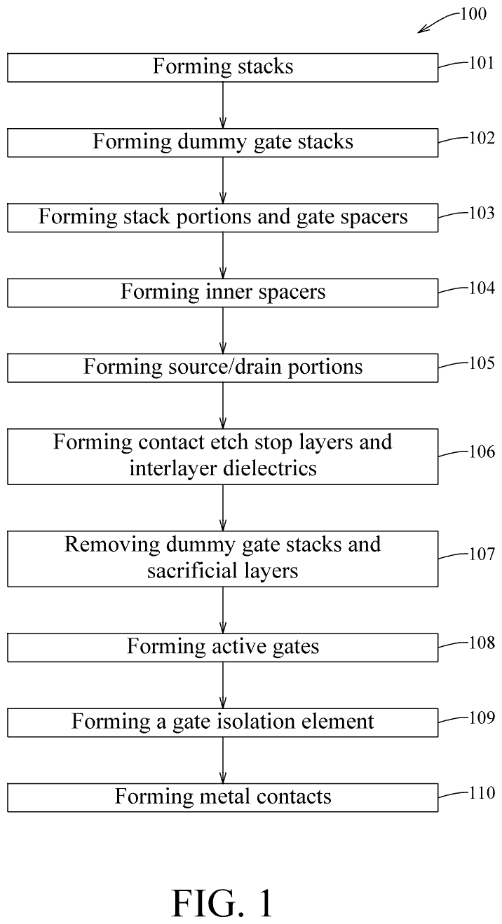

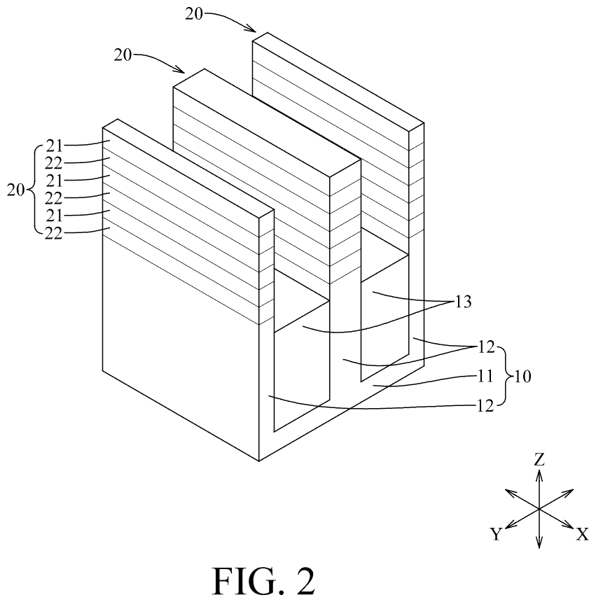

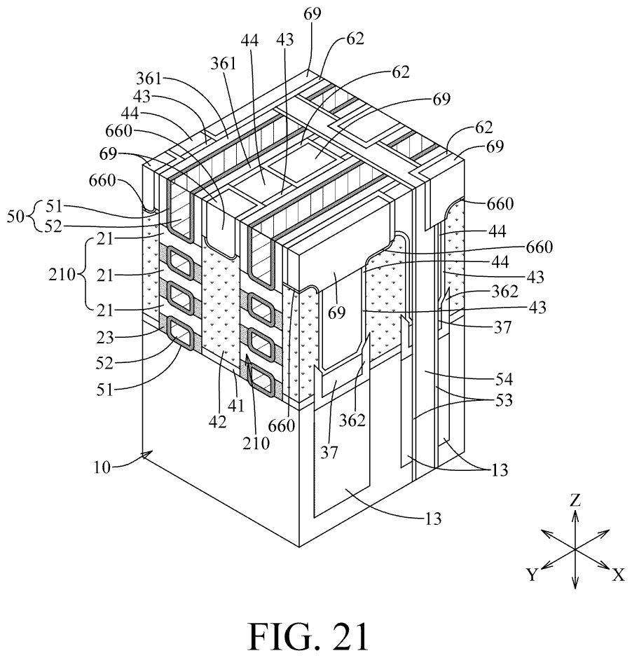

FIG. 1 is a flow diagram illustrating a method 100 for manufacturing the semiconductor structure (for example, the semiconductor structure shown in FIG. 21) in accordance with some embodiments. FIGS. 2 to 21 illustrate schematic views of intermediate stages of the method 100 in accordance with some embodiments. Some repeating structures are omitted in FIGS. 2 to 21 for the sake of brevity. Additional steps can be provided before, after or during the method 100, and some of the steps described herein may be replaced by other steps or be eliminated.

Referring to FIG. 1 and the example illustrated in FIG. 2, the method 100 begins at step 101, where stacks 20 are respectively formed on fins 12 of a substrate 10.

The substrate 10 has a base 11 and the fins 12. The fins 12 are disposed on the base 11 in a Z direction, and are spaced apart from each other in a Y direction transverse to (e.g., perpendicular to) the Z direction. Each of the fins 12 extends in an X direction that transverse to (e.g., perpendicular to) the Z direction and the Y direction. Number of the fins 12 may be determined according to practical needs.

The substrate 10 has an n-type region (not shown) and a p-type region (not shown). The n-type region is to be formed with an n-type device of the semiconductor structure (e.g., an n-type transistor), while the p-type region is to be formed with a p-type device of the semiconductor structure (e.g., a p-type transistor). Please note that the structures shown in FIGS. 2 to 21 are generally applicable to formation of both the n-type device and the p-type device, except otherwise specified. The n-type and p-type devices may be also referred to as semiconductor devices.

In some embodiments, the substrate 10 may be made of elemental semiconductor materials, such as crystalline silicon, diamond, or germanium; compound semiconductor materials, such as silicon carbide, gallium arsenide, indium arsenide, or indium phosphide; or alloy semiconductor materials, such as silicon germanium, silicon germanium carbide, gallium arsenide phosphide, or gallium indium phosphide. The substrate 10 may be doped with p-type impurities or n-type impurities, or undoped. In addition, the substrate 10 may be a bulk silicon substrate, a silicon-on-insulator (SOI) substrate, or a germanium-on-insulator (GOI) substrate. In some embodiments, the substrate 10 may be made of silicon. Other suitable materials for forming the substrate 10 are within the contemplated scope of disclosure.

The stacks 20 are spaced apart from each other in the Y direction. Each of the stacks 20 includes first nanosheet layers 21 and second nanosheet layers 22 that are alternatively disposed on one another in the Z direction. As shown in FIG. 2, each of the stacks 20 has three of the first nanosheet layers 21 and three of the second nanosheet layers 22, but are not limited thereto. In some embodiments, the first nanosheet layers 21 include silicon, and the second nanosheet layer 22 include silicon germanium. Other suitable numbers and/or materials of each of the first and second nanosheet layers 21, 22 are within the contemplated scope of the present disclosure.

In some embodiments, isolation elements 13, or known as shallow trench isolation (STI), are respectively formed between two adjacent ones of the fins 12. Upper surfaces of the isolation elements 13 are are located at a level lower than bottom surfaces of the second nanosheet layers 22. The isolation elements 13 may include silicon oxide, but is not limited thereto. Other suitable materials for forming the isolation elements 13 are within the contemplated scope of the present disclosure.

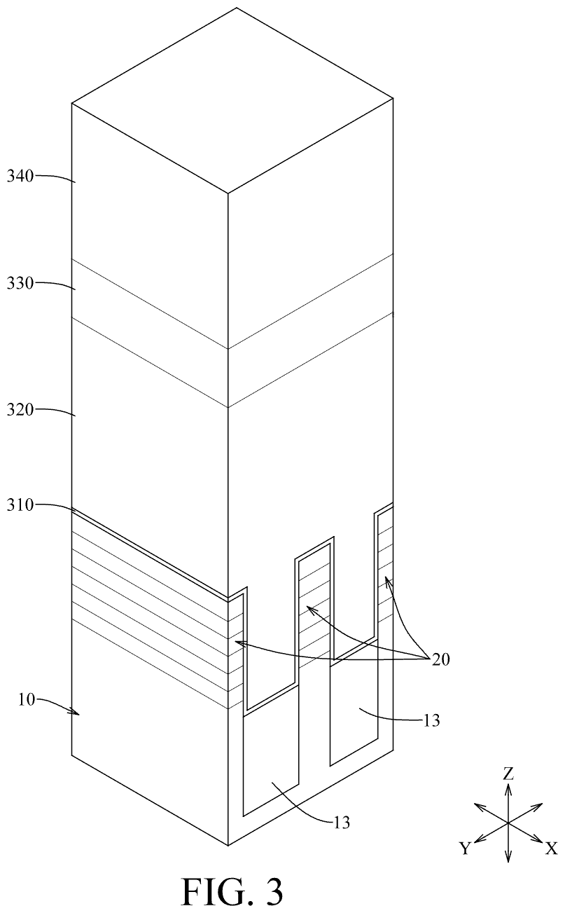

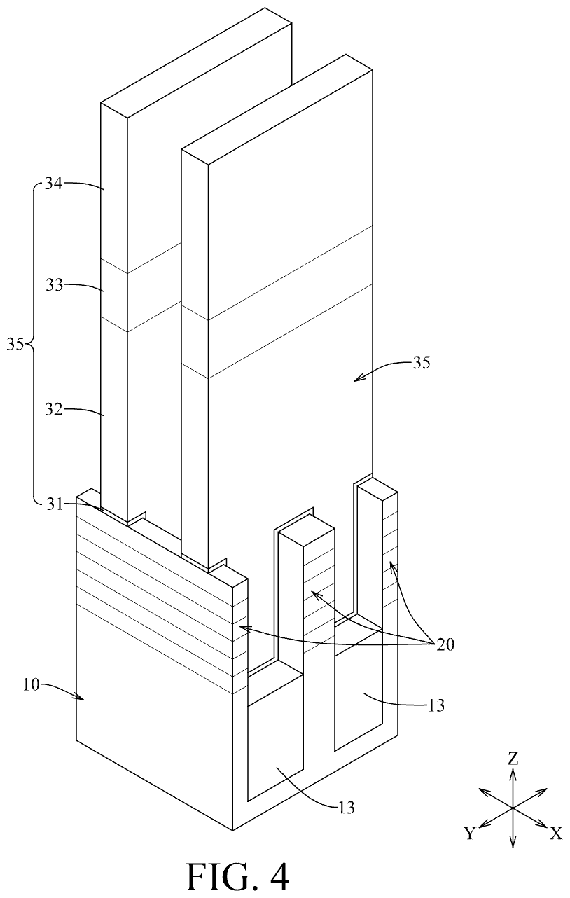

Referring to FIG. 1 and the example illustrated in FIGS. 3 and 4, the method 100 proceeds to step 102, where dummy gate stacks 35 are formed.

Step 102 includes a first sub-step (see FIG. 3) of sequentially depositing a dummy dielectric layer 310, a dummy gate layer 320, a first hard mask layer 330 and a second hard mask layer 340 over the structure shown in FIG. 2, followed by a second sub-step of patterning the layers 310, 320, 330 and 340 so as to form the dummy gate stacks 35. The dummy dielectric layer 310 may include a dielectric material, such as silicon oxide, but is not limited thereto. The dummy gate layer 320 may include polycrystalline silicon, but is not limited thereto. The first hard mask layer 330 and the second hard mask layer 340 are made of different materials, and may each include silicon nitride, silicon oxide, silicon oxynitride, or the likes, but are not limited thereto. In some embodiments, the first hard mask layer 330 includes silicon nitride, while the second hard mask layer 340 includes silicon oxide. Other suitable materials for the dummy dielectric layer 310, the dummy gate layer 320, the first hard mask layer 330 and the second hard mask layer 340 are within the contemplated scope of the present disclosure. In some embodiments, the dummy dielectric layer 310 is conformally formed over the structure shown in FIG. 2.

Referring to FIG. 4, the dummy gate stacks 35 are spaced apart from each other in the X direction. The dummy gate stacks 35 are formed over the stacks 20, and portions of the stacks 20 are exposed from the dummy gate stacks 35. Each of the dummy gate stacks 35 includes a dummy dielectric 31 (formed from the dummy dielectric layer 310), a dummy gate 32 (formed form the dummy gate layer 320), a first hard mask 33 (formed from the first hard mask layer 330), and a second hard mask 34 (formed from the second hard mask layer 340).

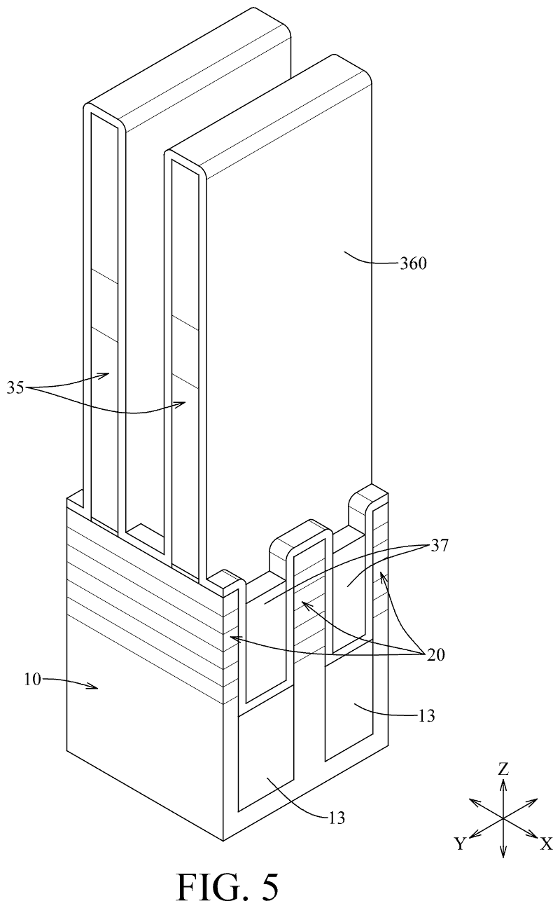

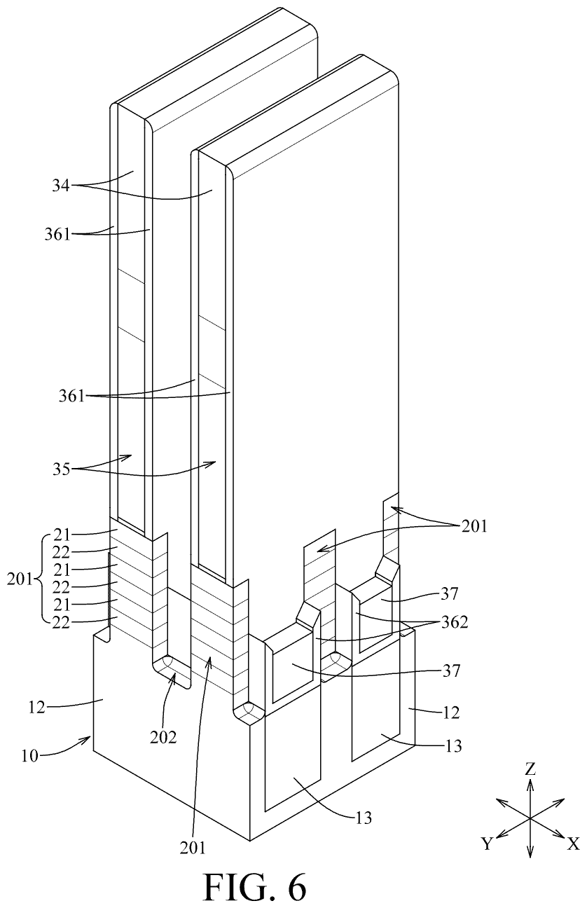

Referring to FIG. 1 and the examples illustrated in FIGS. 5 and 6, the method 100 proceeds to step 103, where each of the stacks 20 is patterned into stack portions 201; and gate spacers 361 and fin sidewalls 362 are formed.

Step 103 includes a first sub-step (see FIG. 5) of conformally forming a spacer material layer 360 (made of silicon oxide, silicon nitride, silicon oxynitride, silicon carbon nitride, silicon oxycarbonnitride, low dielectric constant (k) materials, or other suitable materials, but are not limited thereto) over the structure shown in FIG. 4. In some embodiments, the first sub-step optionally further includes forming STI hard masks 37 (made of silicon oxide, but is not limited thereto) on the spacer material layer 360 over the isolation elements 13. A second sub-step of step 103 is to perform a patterning process to form the gate spacers 361, the fin sidewalls 362 and the stack portions 201 (see FIG. 6). Specifically, in the patterning process, a portion of the second hard mask 34 of each of the dummy gate stacks 35 is removed along with portion of the spacer material layer 360 covering the removed portion of the second hard mask 34, so as to form the gate spacers 361. In addition, parts of each of the stacks 20 (see FIG. 5) that are exposed from the dummy gate stacks 35 are removed along with portions of the spacer material layer 360 covering such removed parts, so as to form the stack portions 201. Moreover, portions of the spacer material layer 360 that are respectively disposed on the isolation elements 13 and exposed from dummy gate stacks 35 are removed along with upper portions of the STI hard masks 37 so as to form the fin side walls 362, and the STI hard masks 37 with reduced height.

After the patterning process, each of the dummy gate stacks 35 is sandwiched by two of the gate spacers 361 in the X direction. Each of the dummy gate stacks 35 and two corresponding ones of the gate spacers 361 cover corresponding ones of the stack portions 201. Two adjacent ones of the stack portions 201 that are located on the same one of the fins 12 are spaced apart from each other by a corresponding one of source/drain recesses 202. Each of the stack portions 201 includes channel layers (which are obtained from the first nanosheet layer 21 and thus are also denoted by reference numeral 21 in FIG. 6 and subsequent figures) and sacrificial layers (which are obtained from the second nanosheet layer 22 and thus are also denoted by reference numeral 22 in FIG. 6 and subsequent figures).

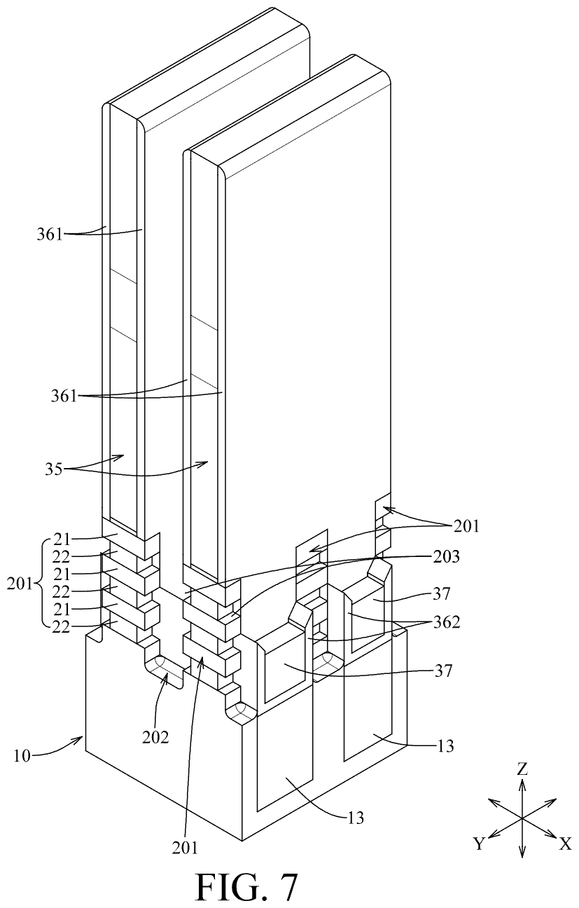

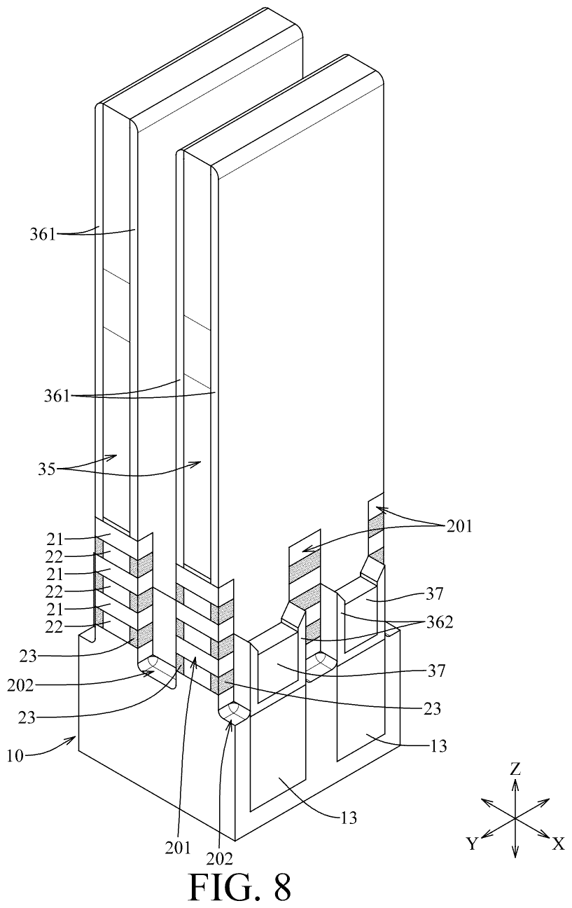

Referring to FIG. 1 and the examples illustrated in FIGS. 7 and 8, the method 100 proceeds to step 104, where opposite ends of the sacrificial layers 22 are removed and replaced by inner spacers 23.

Step 104 includes a first sub-step of, for each of the stack portions 201, removing opposite ends of each of the sacrificial layers 22 in the X direction (see FIG. 7) through the source/drain recesses 202, so as to form cavities 203 beneath the corresponding gate spacers 361. Any suitable methods, such as an etching process, but not limited thereto, may be employed. A second sub-step of step 104 is to form inner spacers 23 respectively in the cavities 203. The inner spacers 23 may include a dielectric material such as silicon oxide, silicon nitride, silicon oxynitride, silicon carbide, or the likes, or combinations thereof. Other suitable materials for the inner spacers 23 are within the contemplated scope of the present disclosure.

Referring to FIG. 1 and the example illustrated in FIG. 9, the method 100 proceeds to step 105, where source/drain portions 42 are respectively formed in the source/drain recesses 202 (see FIG. 8).

In some embodiments, optionally, prior to formation of the source drain portions 42, bottom dielectrics 41 are formed respectively formed in the source/drain recesses 202. The bottom dielectrics 41 may include a dielectric material, such as silicon oxide, silicon nitride, silicon oxynitride, silicon carbide, other suitable materials, or combinations thereof, but are not limited thereto.

Each of the source/drain portions 42 interconnects two adjacent ones of the stack portions 201 located on the same one of the fins 12 in the X direction. In addition, each one of the source/drain portions 42 is located between two adjacent ones of the fin sidewalls 362. The source/drain portions 42 may include a semiconductor material, such as a silicon-containing semiconductor material, e.g., silicon, or silicon germanium, and may include any suitable dopants (such as n-type dopant(s), or p-type dopant(s)). For instance, the source/drain portions 42 in the n-type device may be made of silicon doped with the n-type dopant(s), while the source/drain portions 42 in the p-type device may be made of silicon germanium doped with the p-type dopant(s). In some embodiments, the source/drain portions 42 may be formed using an epitaxy growth process, and each of the source/drain portions 42 may include multiple epitaxy layers. Other suitable materials and/or methods for forming the source/drain portions 42 are within the contemplated scope of the present disclosure.

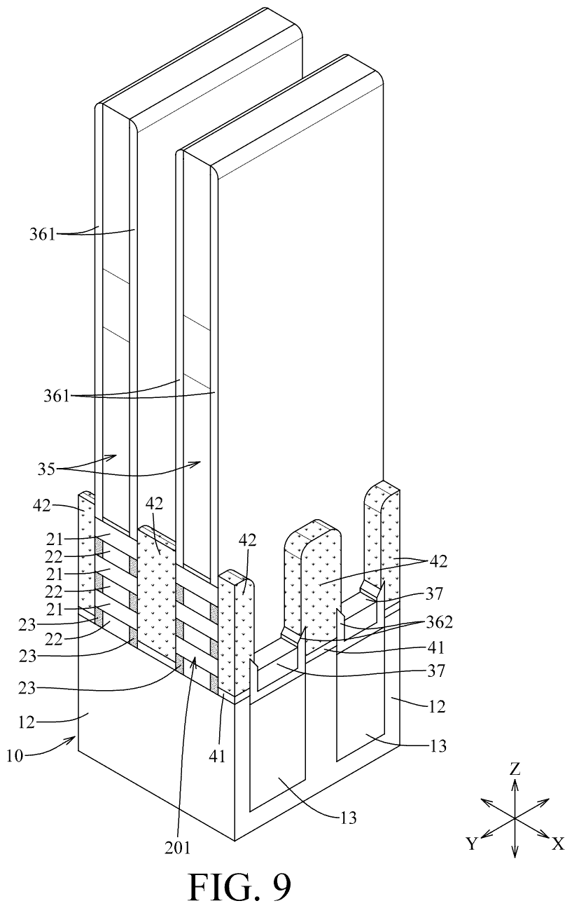

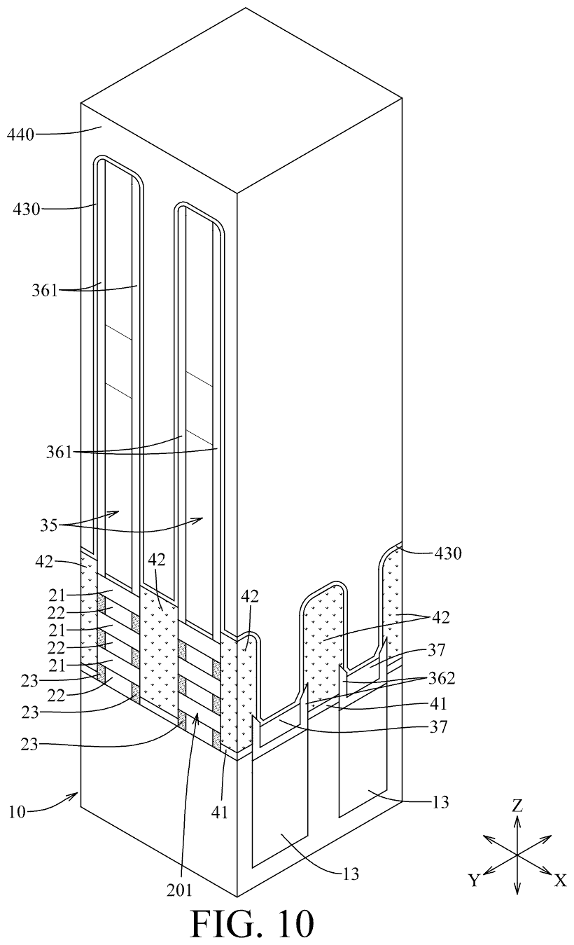

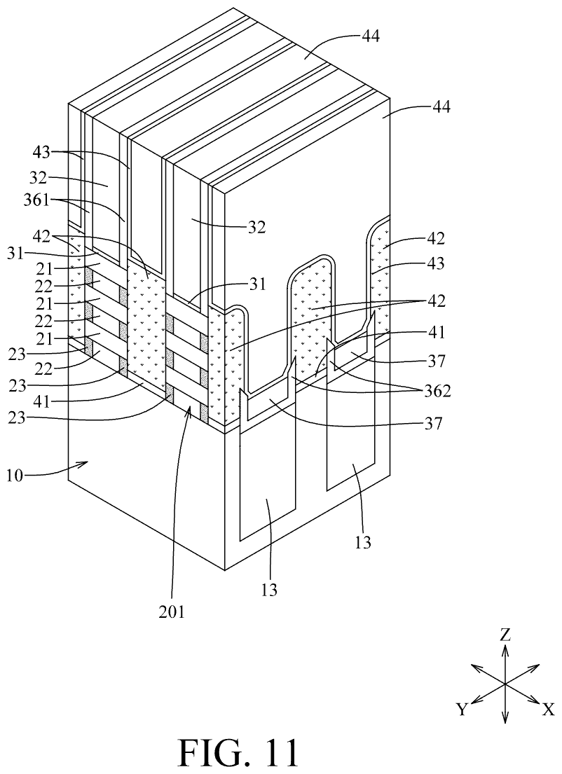

Referring to FIG. 1 and the examples illustrated in FIGS. 10 and 11, the method 100 proceeds to step 106, where contact etch stop layers (CESLs) 43 and interlayer dielectrics (ILDs) 44 are formed.

Step 106 includes a first sub-step of sequentially depositing a CESL material layer 430 and an ILD material layer 440 (see FIG. 10) over the structure shown in FIG. 9. In some embodiments, each of the CESL material layer 430 and the ILD material layer 440 is made of silicon oxide, silicon nitride, silicon oxynitride, phosphosilicate glass, borophosphosilicate glass, spin-on glass, fluorosilicate glass, carbon-doped silicon oxide, xerogel, aerogel, parylene, divinylsiloxane-bis-benzocyclobutene-based dielectric material, polyimide, or other suitable dielectric materials, but the ILD material layer 440 is made of a material different from those of the spacer material layer 360 and the CESL material layer 430. The CESL material layer 430 may be formed in a conformal manner over the structure shown in FIG. 9. In a second sub-step of step 106, the structure shown in FIG. 10 is subjected to a planarization process, such as a chemical mechanical planarization (CMP) process, but is not limited thereto, so as to obtain a structure with the CESLs 43 and the ILDs 44 (see FIG. 11). Specifically, the CMP process is to remove an upper portions of the CESL material layer 430, the ILD material layer 440, the gate spacers 361, and the dummy gate stacks 35. For each of the dummy gate stacks 35, the first hard mask 33, the second hard mask 34 and an upper portion of the dummy gate 32 are removed (see also FIG. 4).

After step 106, the remaining dummy gates 32 (of the dummy gate stacks 35 shown in FIG. 4) are each disposed between two of the CESLs 43 and between two of the ILDs 44 at opposite sides in the X direction. After step 106, dielectric features are obtained, each including one of the ILDs 44 and a corresponding one of the CESLs 43, and each being formed over a corresponding one of the source/drain portions 42.

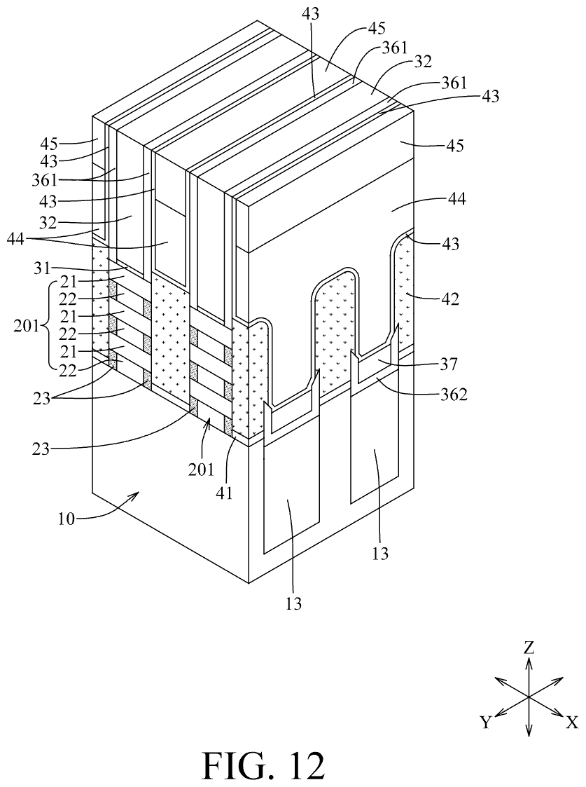

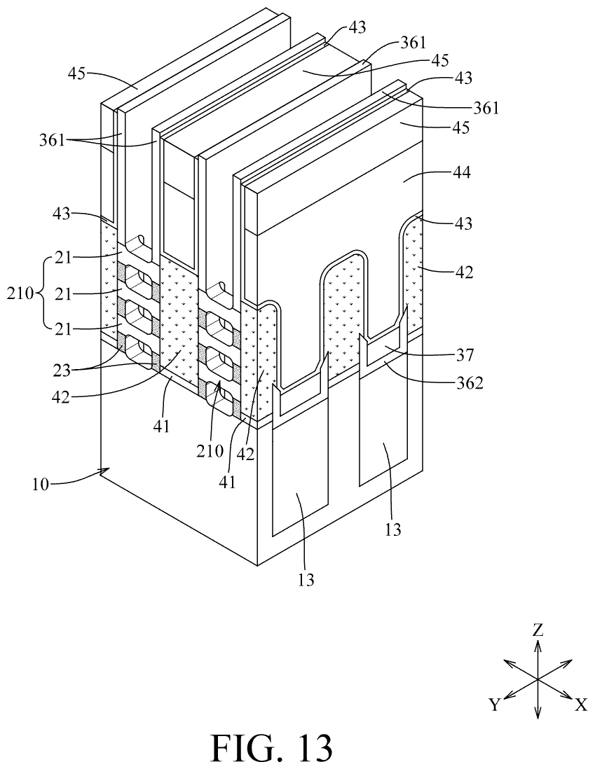

Referring to FIG. 1 and the examples illustrated in FIGS. 12 and 13, the method 100 proceeds to step 107, where the remaining dummy gates 32, the dummy dielectrics 31 (of the dummy gate stacks 35 shown in FIG. 4) and the sacrificial layers 22 are removed.

Step 107 includes a first sub-step of replacing upper portions of the ILDs 44 with third hard masks 45, respectively (see FIG. 12). Any suitable process such as an etching process, but is not limited thereto, may be employed to remove the upper portions of the ILDs 44, followed by forming the third hard masks 45 (made of e.g., silicon nitride, but is not limited thereto) using any suitable deposition process. A second sub-step of step 107 is to remove the remaining dummy gates 32, the dummy dielectrics 31 (of the dummy gate stacks 35, see FIG. 4), and the sacrificial layers 22 of each of the stack portions 201. Any suitable process such as an etching process, but is not limited thereto, may be employed. Other suitable methods for removing the dummy gates 32, the dummy dielectrics 31 and the sacrificial layers 22 are within the contemplated scope of the present disclosure. In some embodiments, step 107 further includes a third sub-step of trimming each of the channel layers 21 in the Z direction.

After the removal process, the channel layers 21 of each of the stack portions 201 (see FIG. 12) remain to serve as a channel portion 210 (see FIG. 13) of a corresponding one of the semiconductor devices (n-type or p-type) formed in the next step. Therefore, after step 107, the stack portions 201 are formed into channel portions 210. Each of the channel portions 210 is disposed between two adjacent ones of the source/drain portions 42

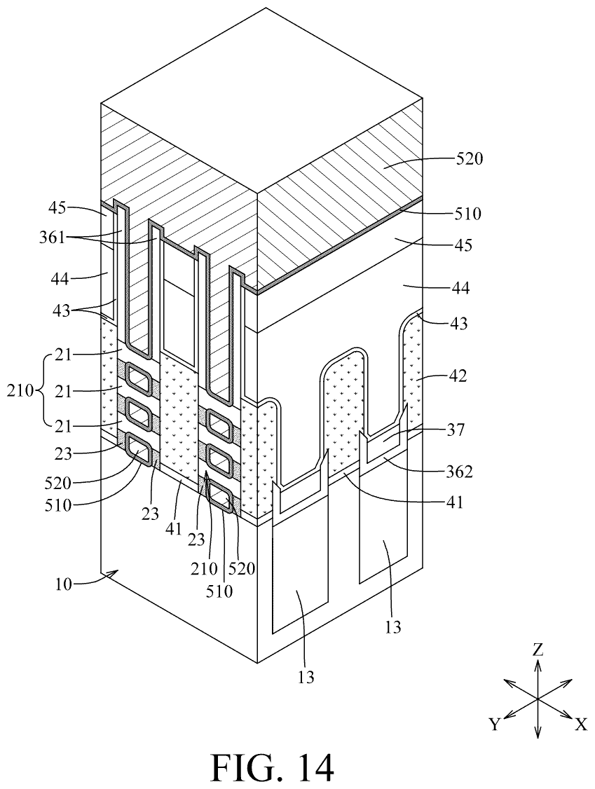

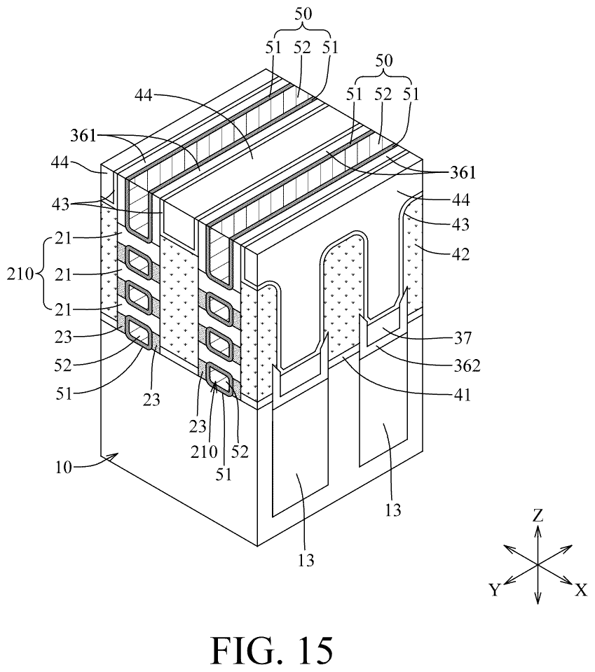

Referring to FIG. 1 and the examples illustrated in FIGS. 14 and 15, the method 100 proceeds to step 108, where active gates 50 are respectively formed around the channel portions 210, thereby obtaining the semiconductor devices. Each of the semiconductor devices includes a corresponding one of the channel portions 210, two corresponding ones of the source/drain portions 42 that are disposed at two opposite sides of the corresponding channel portions 210 in the X direction, a corresponding one of the active gates 50, two corresponding ones of the remaining gate spacers 361 that are located at two opposite sides of the corresponding active gate 50 in the X direction, and two corresponding ones of the dielectric features that are respectively disposed at two opposite sides of the active gate 50 in the X direction.

In a first sub-step of step 108, a gate dielectric material layer 510 and a gate electrode material layer 520 (see FIG. 14) are sequentially formed over the structure shown in FIG. 13. The gate dielectric material layer 510 may include a high dielectric constant material (e.g., hafnium oxide), but is not limited thereto. The gate electrode material layer 520 may include a conductive material such as a metal, a metal-containing nitride, a metal-containing silicide, a metal-containing carbides, but are not limited thereto. In some embodiments, the gate dielectric material layer 510 is formed in a conformal manner. In a second sub-step of step 108, a planarization process, e.g., the CMP process, is performed to remove an upper portion of the structure shown in FIG. 14, so as to obtain the structure shown in FIG. 15. Specifically, the third hard masks 45, and portions of each of the gate electrode material layer 520, the gate dielectric material layer 510, the gate spacers 361, the ILDs 44, the CESLs 43 (see FIG. 14) are removed in the planarization process.

After step 108, the active gates 50 are obtained. Each of the active gates 50 include a gate dielectric 51 (originates from the gate dielectric material layer 510) and a gate electrode 52 (originates from the gate electrode material layer 520). Each of the active gates 50 includes an upper section and a lower section. In the lower section, the gate dielectric 51 and the gate electrode 52 are formed around each of the channel layers 21 of a corresponding one of the channel portions 210. In the upper section, the gate dielectric 51 is disposed on an uppermost one of the channel layers 21 of the corresponding channel portion 21 and further extends to cover surfaces of the two corresponding gate spacers 361 such that the gate electrode 52 is spaced apart from the two corresponding gate spacers 361 by the gate dielectric 51.

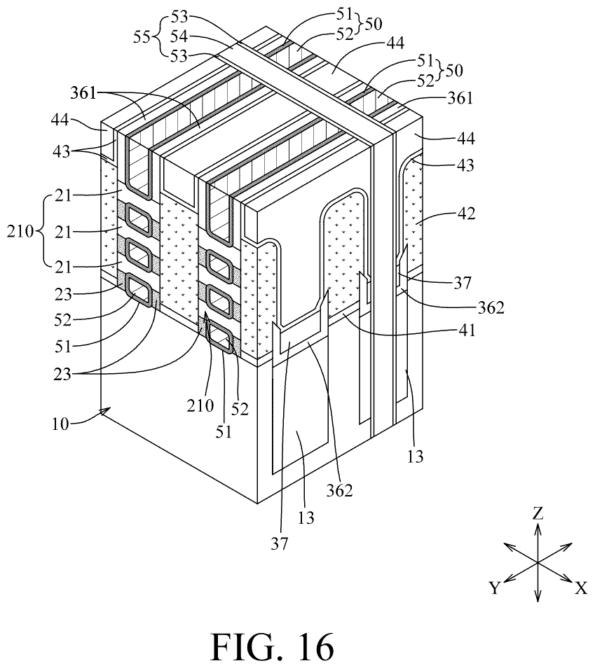

Referring to FIG. 1 and the example illustrated in FIG. 16, the method 100 proceeds to step 109, where a gate isolation element 55 is formed.

Step 109 may also be known as a “cut metal gate” process. The gate isolation element 55 is configured to form at least one of the active gate 50 into sections that are electrically isolated from each other. As shown in FIG. 16, each of the active gates 50 is formed into two sections by the gate isolation element 55.

Step 109 may include forming a recess (not shown) at a position that is desired to form the gate isolation element 55, followed by forming the gate isolation element 55. In some embodiments, the recess may penetrate the structure in the Z direction until reaching corresponding one(s) of the isolation elements 13. In some embodiments, the gate isolation element 55 includes multiple layers that are made of different dielectric materials. For instance, as shown in FIG. 16, the gate isolation element 55 includes an outer dielectric 53 made of silicon nitride, but is not limited thereto, and an inner dielectric 54 made of silicon oxide, but is not limited thereto (the inner dielectric 54 is spaced apart from the active gates 50 by the outer dielectric 53). Other suitable materials and/or configurations and/or methods for forming the gate isolation element 55 are within the contemplated scope of the present disclosure.

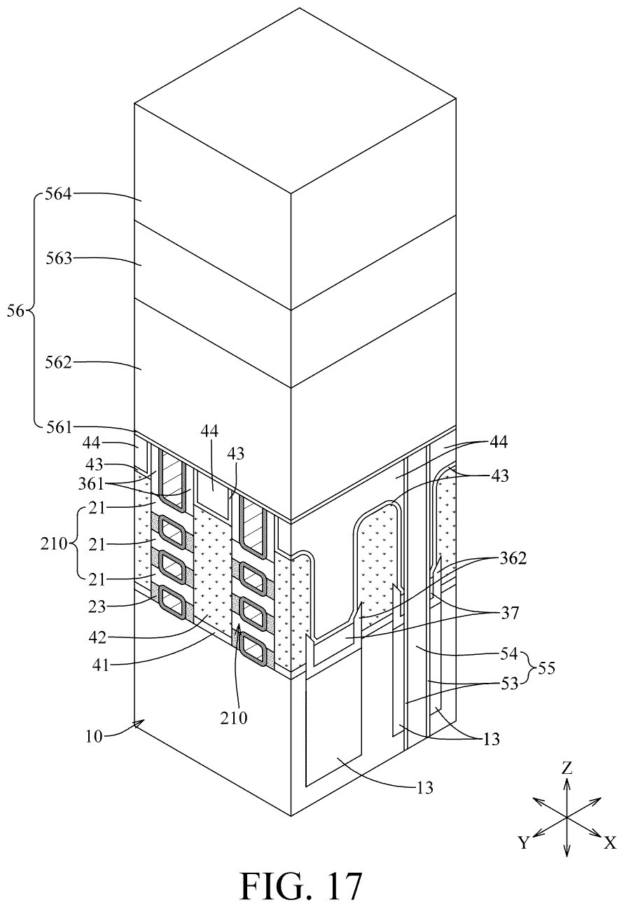

Referring to FIG. 1 and the examples illustrated in FIGS. 17 to 21, the method 100 proceeds to step 110, where metal contacts 69, or known as MD metals are formed.

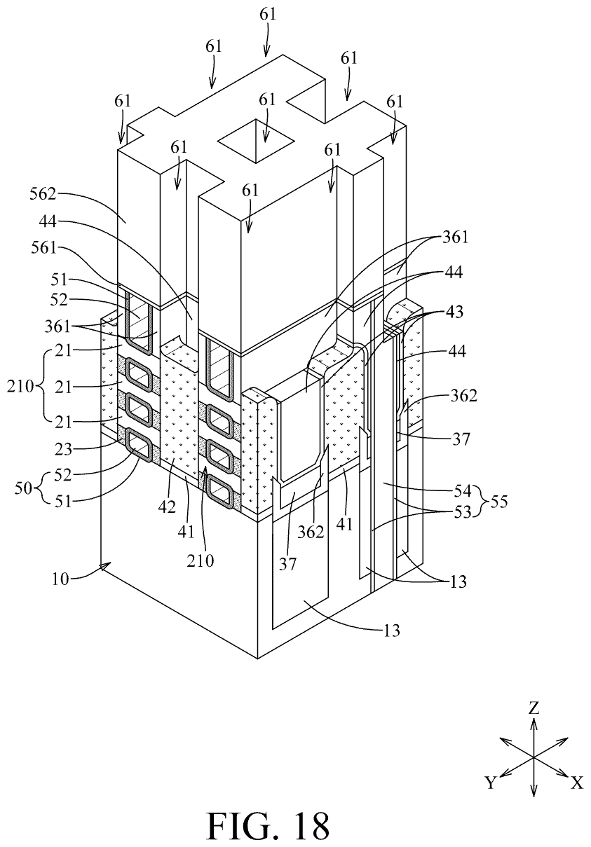

Referring to FIGS. 17 and 18, a MD hard mask 56 (see FIG. 17) is first formed on the structure shown in FIG. 16, followed by a patterning process of the MD hard mask so as to obtain the structure shown in FIG. 18. In some embodiments, the MD hard mask 56 includes a dielectric layer 561 (made of a dielectric material different from the material of the ILDs 44), a dielectric layer 562 (made of a dielectric material different from that of the dielectric layer 561), and two different hard mask layers 563, 564 (each of which is made of different materials selected from metal materials and dielectric materials), and the layers 561, 562, 563, 564 are sequentially formed on a top surface of the semiconductor device obtained. Other suitable materials and/or components for the MD hard mask 56 are within the contemplated scope of the present disclosure. In some embodiments, the patterning process involves a photolithography process and an etching process to pattern the MD hard mask 56 as well as the ILDs 44 and the CESLs 43, so as to form trenches 61 that respectively expose the source/drain portions 42 underneath. After the patterning process, the patterned dielectric layers 561, 562 are remained as shown in FIG. 18, and the hard mask layers 563, 564 are also removed during patterning the ILDs 44 and the CESLs 43.

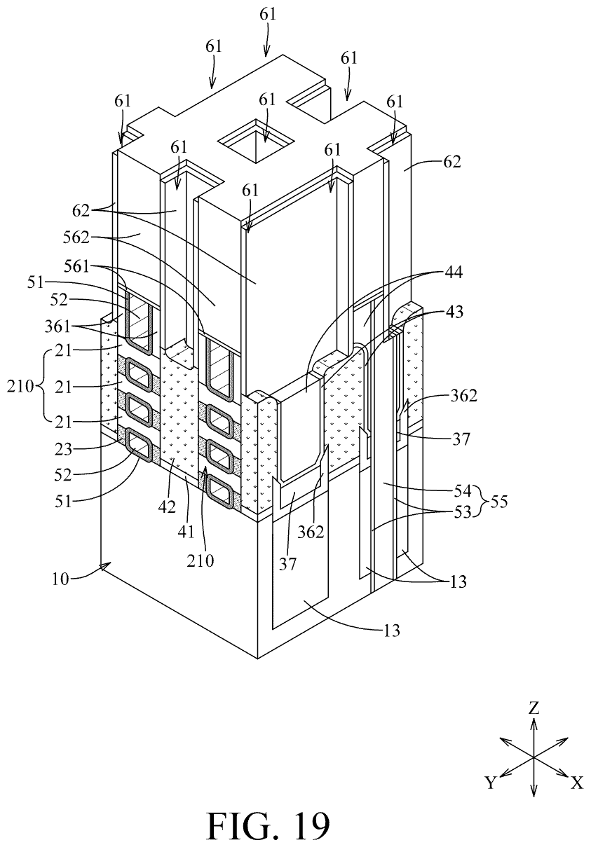

Referring to FIG. 19, MD spacer layers 62 are respectively formed along sidewalls of the trenches 61. In some embodiments, formation of the MD spacers 62 involves conformally forming a MD spacer material layer (not shown) over the structure shown in FIG. 18, followed by an antistrophic etching to remain portions of the MD spacer material layer located on the sidewalls of the trenches 61, thereby forming the MD spacer layers 62. In certain embodiments, the MD spacer material layer 62 includes silicon nitride, or other suitable materials.

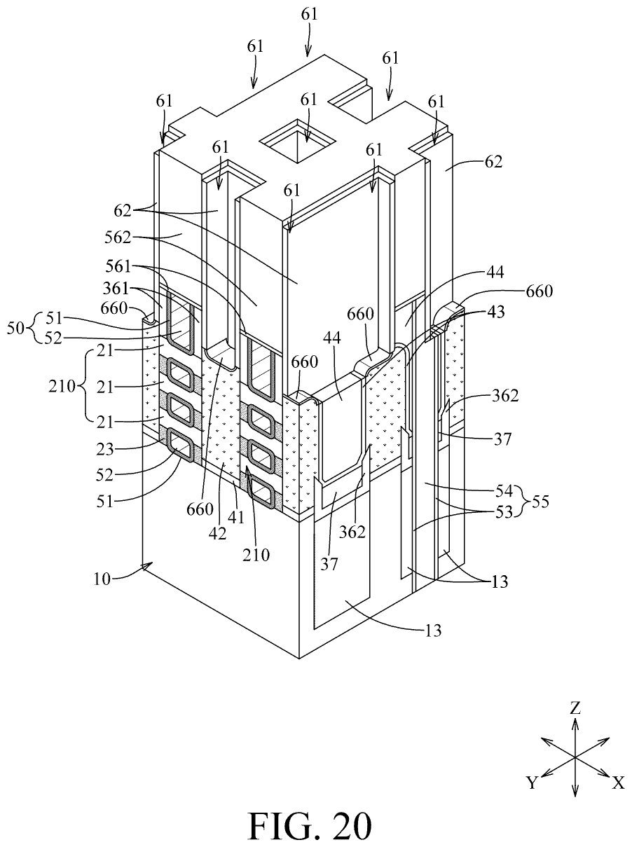

Referring to FIG. 20, metal silicide layers 660 are formed at bottoms of the trenches 61, respectively. In some embodiments, metal layers (not shown) for forming the metal silicide layers 660 are first formed along sidewalls and bottoms of the trenches 61. Silicon of the source/drain portions 42 diffuse to portions of the metal layers that are disposed at bottoms of the trenches 61, and react with metal thereof to form the metal silicide layers 660, respectively. The metal layers for forming the metal silicide layers 660 may include or be made of nickel, platinum, palladium, cobalt, titanium, erbium, zirconium, hafnium, ruthenium, other suitable metal materials, or combinations thereof. That is, the metal silicide layers 660 may include or be made of nickel silicide, platinum silicide, palladium silicide, cobalt silicide, titanium silicide, erbium silicide, zirconium silicide, hafnium silicide, ruthenium silicide, other suitable metal silicide materials, or combinations thereof. Each of the metal silicide layers 660 include a lower portion, and a surrounding portion that extend upwardly from a periphery of the lower portion. The lower portion includes mainly the metal silicide, while the surrounding portion includes mainly the metal. In some embodiments, as shown in FIG. 20, the surrounding portion is removed, and only the lower portion remains. In other embodiments, the surrounding portion also remains.

Referring to FIG. 21, metal contacts 69 are formed in the trenches 61 (see FIG. 20), respectively. In some embodiments, metal filling layers (not shown) for forming the metal contacts 69 are formed to fill the trenches 61, so that the metal contacts 69 are connected to the source/drain portions 42 through the metal silicide layers 660 in the Z direction, respectively.

In some embodiments, formation of the metal contacts 69 further includes forming a dipole metal layer (not shown in FIG. 21) between each of the metal silicide layers 660 and a respective one of the source/drain portions 42. The dipole metal layer is configured to induce formation of interfacial dipole between each of the metal silicide layers 660 and the respective one of the source/drain portions 42, with positive charges above an upper surface of the respective source/drain portion 42, and negative charges below the upper surface of the respective source/drain portion 42, so as to result in formation of a local electric field. Such local electric field may tune and shift band alignment, resulting in effective reduction of Schottky barrier height (SBH) and contact resistance (Rcsd) of the device, and thus improved performance of the device. In some cases, the dipole metal layer is formed along each of the trenches 61 (see FIG. 20), resulting in the capacity of each of the trenches 61 available for forming the respective metal contact 69 being undesirably reduced. Therefore, in some embodiments of the present disclosure, a lateral portion of the dipole metal layer is removed, so that a larger capacity is available to form the metal contacts 69.

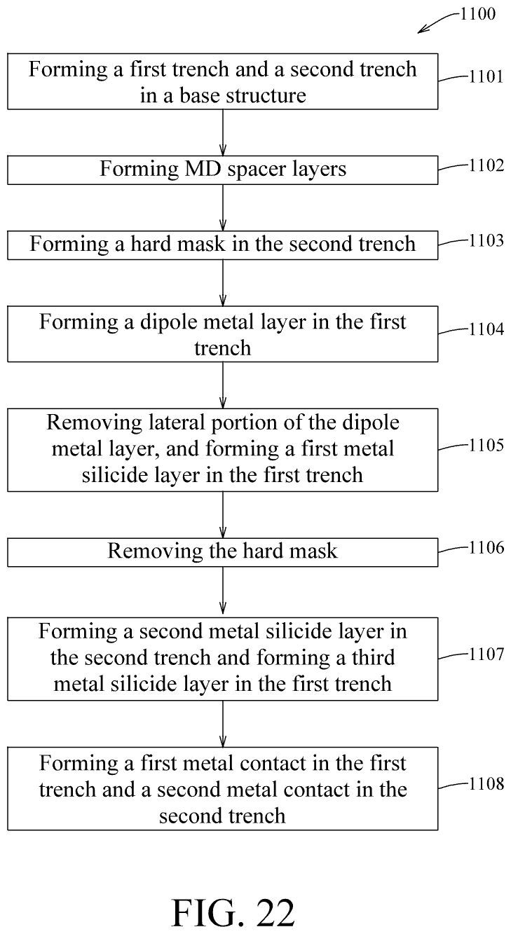

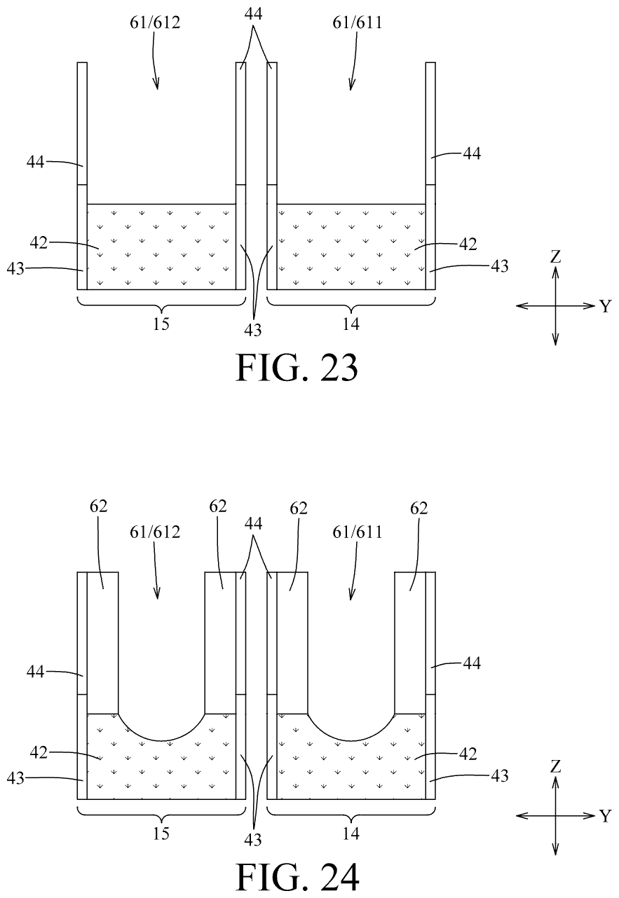

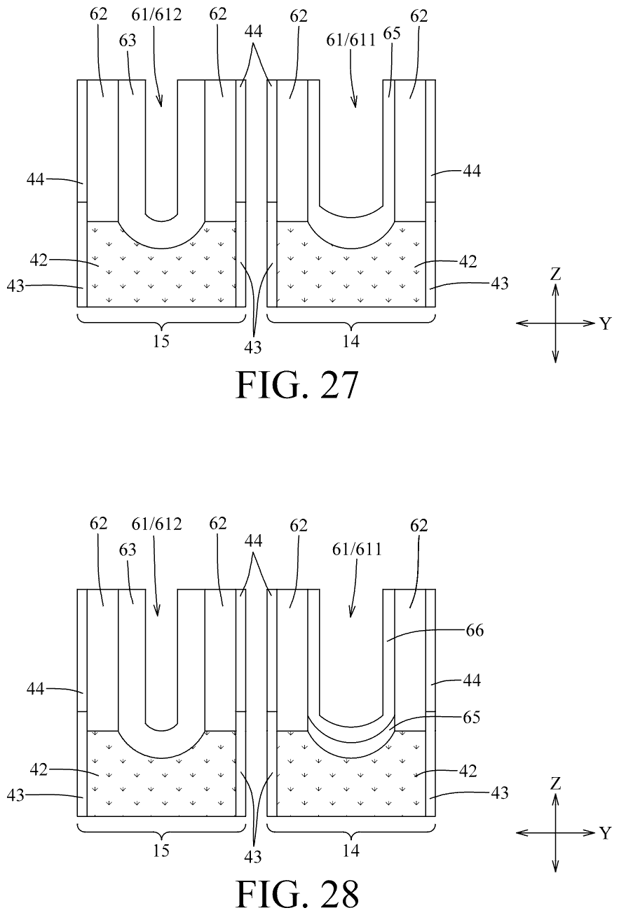

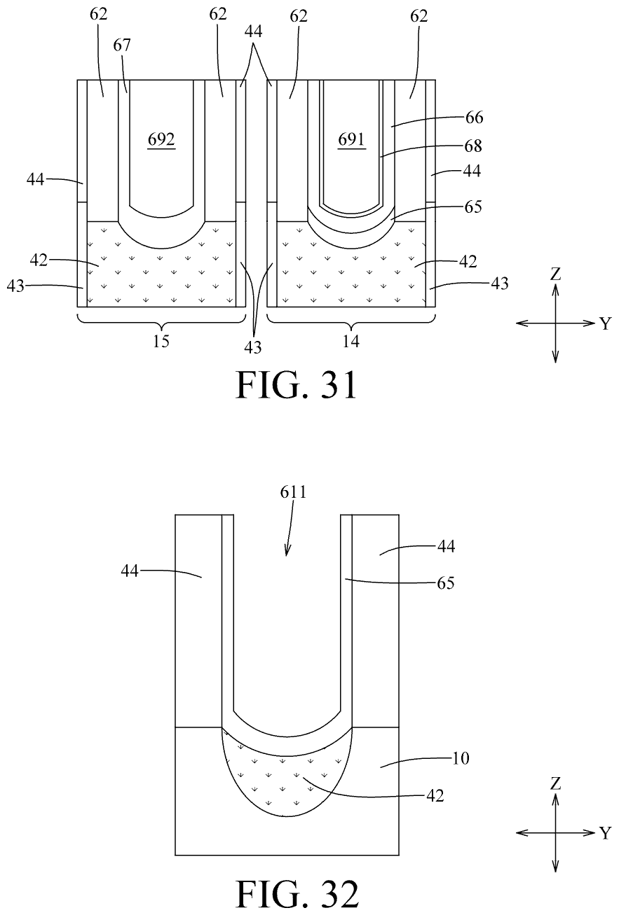

FIG. 22 is a flow diagram illustrating a method 1100 for manufacturing the metal contacts in the n-type device and the p-type device, in accordance with some embodiments. The metal contacts formed in the n-type device are denoted by the numeral 691 (see FIG. 31, only one of which is shown). The metal contacts formed in the p-type device are denoted by the numeral 692 (see FIG. 31, only one of which is shown). Specifically, step 110 of the method 100 as described with reference to FIGS. 17 to 21 are described in more details by steps 1101 to 1108 of the method 1100. FIGS. 23 to 31 illustrate schematic views of intermediate stages of the method 1100 in accordance with some embodiments. Some repeating structures are omitted in FIGS. 23 to 31 for the sake of brevity. Additional steps can be provided before, after or during the method, and some of the steps described herein may be replaced by other steps or be eliminated. In the exemplary embodiment shown in FIGS. 22 to 31, the dipole metal layer, and the dipole metal feature formed thereby (both of which are denoted by the numeral 65 as shown in FIGS. 27 and 28) are only formed in the n-type device, but is not limited thereto. The dipole metal feature is formed by removing lateral portions of the dipole metal layer, leaving a bottom portion of the dipole metal layer to serve as the dipole metal feature. Please note that the dipole metal feature may also be formed in the p-type device, or the n-type device, or in both the p-type and n-type device.

Referring to FIG. 22 and the example illustrated in FIG. 23, the method 1100 begins at step 1101, where the trenches 61 (i.e., first trenches 611 and second trenches 612) are formed in a base structure.

Specifically, the base structure may be the structure shown in FIG. 16. Each of the dielectric features (each including one of the ILDs 44 and a corresponding one of the CESLs 43) serves as one of dielectric material-based features of the base structure, and the source/drain portions 42 each serves as a semiconductor material-based feature of the base structure. Please note that the structure shown in FIG. 16 may be an n-type device, or a p-type device.

The first trenches 611 are formed in the dielectric material-based features of the n-type device at an n-type region 14, while the second trenches 612 are formed in the dielectric material-based features of the p-type device at a p-type region 15. Each of the n-type device and the p-type device may have a structure shown in FIG. 16. Referring to FIG. 23 and the subsequent figures, only one of the trenches 611 and only one of the trenches 612, taken along the Y direction, are shown and discussed below, with reference to the cross sectional views thereof. During formation of each of the first and second trenches 611, 612, a corresponding one of the dielectric material-based features is patterned into two parts which are spaced apart from each other in the Y direction. In some embodiments, each of the first and second trenches 611, 612 may be one of the trenches 61 shown in FIG. 18. In each of the first and second trenches 611, 612, two parts of the corresponding one of the dielectric material-based features, and a bottom corresponding one of the source/drain portions 42 are shown in FIG. 23 and subsequent figures, and other elements (e.g., the patterned dielectric layers 561, 562, the substrate 10, the two adjacent corresponding ones of the gate spacers 361 opposite to each other in the X direction, and so on) are omitted in FIG. 23 and subsequent figures. Please note that, in the two parts of the corresponding one of the dielectric material-based features in each of the first and second trenches 611, 612, two parts of the corresponding ILD 44 spaced apart from each other by the trench 61 in the Y direction and two parts of the corresponding CESL 43 respectively located beneath the two parts of the corresponding ILD 44 are shown in FIG. 23 and subsequent figures; and one part of the corresponding ILD 44 and one part of the corresponding CESL 43 in the trench 61 are shown in FIG. 18.

In step 1101, the first and second trenches 611, 612 are each formed to expose the bottom corresponding one of the source/drain portions 42. Formation of the first and second trenches 611, 612 are similar to the description with reference to FIGS. 17 and 18, and details thereof are omitted for the sake of brevity. Referring to FIG. 23, for each of the first and second trenches 611, 612, a sidewall thereof is bordered by the dielectric material-based feature (e.g., the two parts of the corresponding ILD 44 and the two parts of the corresponding CESL 43) and the two adjacent corresponding gate spacers 361 (see FIG. 18), while a bottom wall thereof is bordered by a semiconductor material-based feature e.g., the bottom corresponding source/drain portion 42. The dielectric material-based feature includes a dielectric material, e.g., silicon oxide, silicon nitride, silicon oxynitride, silicon oxynitride, phosphosilicate glass, borophosphosilicate glass, spin-on glass, fluorosilicate glass, carbon-doped silicon oxide, xerogel, aerogel, parylene, divinylsiloxane-bis-benzocyclobutene-based dielectric material, polyimide, or other suitable dielectric materials, but are not limited thereto. The semiconductor material-based feature includes a silicon-containing semiconductor material, such as one of silicon and silicon germanium, but are not limited thereto. Other suitable materials for the dielectric material-based feature and/or the semiconductor material-based feature are within the contemplated scope of the present disclosure.

Referring to FIG. 22 and the example illustrated in FIG. 24, the method 1100 proceeds to step 1102, where the MD spacer layers 62 are formed. Formation of the MD spacer layers 62 are similar to the description with reference to FIG. 19, and details thereof are omitted for the sake of brevity. After step 1102, each of the MD spacer layers 62 is formed on the sidewall of a respective one of the first and second trenches 611, 612 (i.e., the two parts of the corresponding ILD 44, the two parts of the corresponding CESL 43, and the two adjacent corresponding gate spacers 361 (see FIG. 18)).

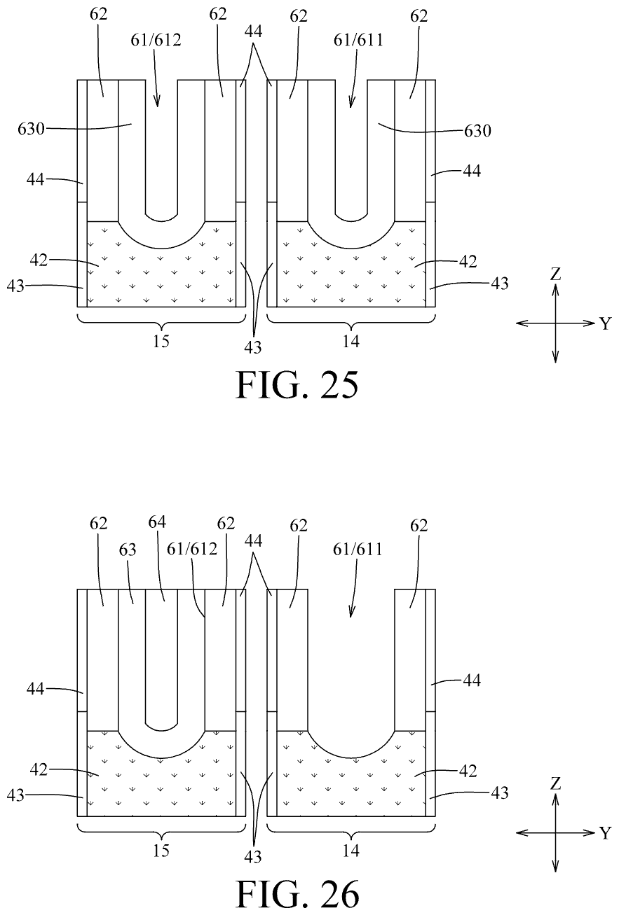

Referring to FIG. 22 and the examples illustrated in FIGS. 25 and 26, the method 1100 proceeds to step 1103, where a hard mask 63 is formed in the second trench 612.

Step 1103 may include a first sub-step of forming a hard mask material layer 630 (see FIG. 25, only portions of the hard mask material layer 630 that are located in the first and second trenches 611, 612 are shown) over the semiconductor structure to cover the first and second trenches 611, 612. A second sub-step of step 1103 is to perform a photolithography process to expose the first trench 611, while the second trench 612 remain protected (see FIG. 26, a photoresist 64 is developed for protection of the trench 612). After the second sub-step of step 1103, the hard mask material layer 630 is formed into the hard mask 63.

Referring to FIG. 22 and the example illustrated in FIG. 27, the method 1100 proceeds to step 1104, where a dipole metal layer 65 is formed in the first trench 611. The dipole metal layer 65 has a lateral portion formed along the sidewall of the first trench 611 and a bottom portion formed along the bottom wall of the first trench 611. The lateral portion is formed on the dielectric material-based feature (e.g., the two parts of the corresponding ILD 44 and the two parts of the corresponding CESL 43) and the two adjacent corresponding gate spacers 361 (see FIG. 18), and the bottom portion is formed on the semiconductor material-based feature e.g., the bottom corresponding source/drain portion 42.

In some embodiments, for the n-type device, the dipole metal layer 65 includes one of zirconium (Zr), hafnium (Hf), antimony (Sb), cerium (Ce), scandium (Sc), yttrium (Y), ytterbium (Yb), erbium (Er), dysprosium (Dy), lanthanum (La), gadolinium (Gd), aluminum (Al), tungsten (W), titanium (Ti), zinc (Zn), beryllium (Be) and combinations thereof. In other embodiments, for the p-type device, the dipole metal layer includes molybdenum (Mo), nickel (Ni), ruthenium (Ru), iridium (Ir), palladium (Pd), platinum (Pt), niobium (Nb), tungsten (W), cobalt (Co), chromium (Cr), osmium (Os), Rhenium (Rc), rhodium (Rh), iron (Fc), manganese (Mn), vanadium (V), tantalum (Ta), and combinations thereof. Other suitable materials for the dipole metal layer 65 are within the contemplated scope of the present disclosure.

The dipole metal layer 65 may be formed by a chemical vapor deposition (CVD) process, a plasma-enhanced CVD (PECVD) process, an atomic layer deposition (ALD) process, a plasma-enhanced ALD (PEALD) process, but are not limited thereto. The dipole metal layer 65 may be formed using a halide of the desired metal, such as a metal chloride, a metal fluoride, a metal bromide, a metal iodide, or the likes. In some embodiments, examples of the halide of the desired metal are zirconium tetrachloride (ZrCl₄), hafnium tetrachloride (HfCl₄), antimony trichloride (SbCl₃), antimony pentachloride (SbCl₅), or other suitable precursors. The precursor reacts with hydrogen to form the desired metal that is deposited in the trench, and hydrogen halide is released to the chamber (such reaction may be expressed by the chemical reaction of MX_{f}+f/2H₂→M+fHX, where M represents the desired metal for the dipole metal layer as aforementioned and X represents a halide used for forming the dipole metal layer, f represents number of halogen atom in the halide of the desired metal). The deposition process may be conducted at a process temperature ranging from about 100° C. to about 500° C., with an ampoule temperature (of the precursor for forming the dipole metal layer 65) ranging from about 25° C. to about 220° C. The deposition process may be conducted at a pressure condition ranging from about 1 Torr to about 9 Torr. The deposition process may be a thermal process, or a plasmas-based process conducted with an optional RF power ranging from about 100 W to about 1000 W, but is not limited thereto. Hydrogen may have a flow rate ranging from about 10 sccm to about 4000 sccm. The precursor may have a flow rate ranging from about 1 sccm to about 100 sccm. Argon serving as a carrier gas may have a flow rate ranging from about 1000 sccm to about 3000 sccm. The aforesaid parameters allow the dipole metal layer 65 to be formed with a good film quality, such as sufficient thickness, good film roughness, low chlorine impurity, and thin lateral portion. Other suitable processes and/or parameters for forming the dipole metal layer 65 are within the contemplated scope of the present disclosure.

In some embodiments, the dipole metal layer 65 may have a thickness ranging from about 0.5 nm to about 5 nm. Such range allows formation of the interfacial dipole, as well as the local electric field, so as to ensure electrical properties of the resultant n-type device. In certain embodiments, the lateral portion is, ideally, formed with a smaller thickness than that of the bottom portion, when the formation of the dipole metal layer 65 has a higher selectivity to the sidewall of the first trench 611 than to the bottom wall of the first trench 611.

Referring to FIG. 22 and the example illustrated in FIG. 28, the method 1100 proceeds to step 1105, where the lateral portion of the dipole metal layer 65 is removed, and a first metal silicide layer 66 is formed along the sidewall and the bottom wall of the first trench 611 on top of the bottom portion of the dipole metal layer 65.

The steps 1104 and 1105 described with reference to FIGS. 27 and 28 are further illustrated in FIGS. 32, 33 and 34.

Specifically, referring to FIG. 32, the structure shown in FIG. 32 corresponds to the step 1104 shown in FIG. 27, in which the dipole metal layer 65 is formed along the sidewall and the bottom wall of the first trench 611, and details thereof are omitted for the sake of brevity.

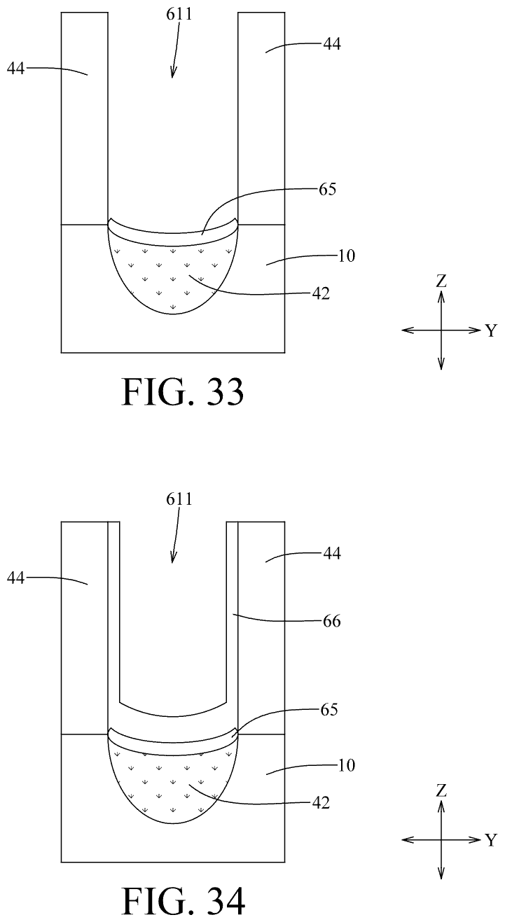

Referring to FIG. 33, the structure shown in FIG. 32 is subjected to an etching process. The etching process may also be referred as a soaking process, since during the etching process, the structure shown in FIG. 32 is placed in a chamber, and an etchant gas is introduced into the chamber, such that the structure is soaked in the etchant gas. The etchant has a higher etching selectivity to the lateral portion than to the bottom portion, so that the lateral portion of the dipole metal layer 65 is removed, and that the bottom portion of the dipole metal layer 65 is at least partially remained.

In some embodiments, the etchant includes a metal halide, and/or a hydrogen halide. Examples of the metal halide are nickel halide (e.g., nickel fluoride (NiF₂), nickel dichloride (NiCl₂), nickel bromide (NiBr₂), nickel iodide (NiI₂), and so on), platinum halide (e.g., platinum difluoride (PtF₂), platinum trifluoride (PtF₃), platinum tetrachloride (PtCl₄), platinum dichloride (PtCl₂), platinum bromide (PtBr₂), platinum diiodide (PtI₂), platinum tetraiodide (PtI₄), and so on), palladium halide (e.g., palladium difluoride (PdF₂), palladium trifluoride (PdF₃), palladium tetrafluoride (PdF₄), palladium hexafluoride (PdF₆), palladium dichloride (PdCl₂), palladium trichloride (PdCl₃), palladium tetrachloride (PdCl₄), palladium dibromide (PdBr₂), palladium tetrabromide (PdBr₄), palladium diiodide (PdI₂), palladium tetraiodide (PdI₄), and so on), cobalt halide (e.g., cobalt difluoride (CoF₂), cobalt trifluoride (CoF₃), cobalt dichloride (CoCl₂), cobalt trichloride (CoCl₃), cobalt iodide (CoI₂), and so on), titanium halide (e.g., titanium trifluoride (TiF₃), titanium tetrafluoride (TiF₄), titanium dichloride (TiCl₂), titanium trichloride (TiCl₃), titanium tetrachloride (TiCl₄), titanium dibromide (TiBr₂), titanium tribromide (TiBr₃), titanium tetrabromide (TiBr₄), titanium diiodide (TiI₂), titanium tetraiodide (TiI₄), and so on), erbium halide (e.g., erbium difluoride (ErF₂), erbium trifluoride (ErF₃), erbium trichloride (ErCl₃), erbium tribromide (ErBr₃), erbium triiodide (ErI₃), and so on), zirconium halide (e.g., zirconium dibromide, zirconium dichloride, zirconium difluoride, zirconium diiodide, zirconium tribromide, zirconium trichloride, zirconium trifluoride, zirconium triiodide, zirconium tetrabromide, zirconium tetrachloride, zirconium tetrafluoride, zirconium tetraiodide), hafnium halide (e.g., hafnium triiodide, hafnium tetrabromide, hafnium tetrachloride, hafnium tetrafluoride, hafnium tetraiodide), ruthenium halide (e.g., ruthenium dichloride, ruthenium tribromide, ruthenium trichloride, ruthenium trifluoride, ruthenium triiodide, ruthenium tetrachloride, ruthenium tetrafluoride) or combinations thereof. Such metal halide has an etching selectivity to the lateral portion than to the bottom portion of about 20:1 to about 10:1. The reaction between metal halide and metal of the dipole metal layer 65 may be expressed in the chemical reaction(s):

M(s)+NYₐ(g)→MY_{b}(g)+NYₑ(g)

where M represents the desired metal for the dipole metal layer 65,
N represents a metal atom of the metal halide,
Y represents a halogen atom of the metal halide,
each of a, b and c ranges from about 2 to about 6, and
a=b+c.
   Please note that the metal halide, or the etchant, is introduced in a gas phase. The resultant MY_{b} or NY_{c} (depending on type of metal of the dipole metal layer 65) is also in gas phase and removed from the ILD 44.

The high etching selectivity originates from the fact that each of the lateral portion and the bottom portion includes different amount of silicon atoms. The bottom portion, which includes a metal, is formed on a semiconductor-based material (see FIG. 32, wherein the semiconductor material-based material includes a silicon-containing semiconductor material, such as silicon or silicon germanium, but is not limited thereto). The silicon atoms in the semiconductor-based material are loosely bonded to each other, and the loose bonding tends to break, so the silicon atoms diffuse into the metal of the bottom portion. As such, the bottom portion includes a certain amount of silicon atoms. In contrast, the lateral portion, which includes a metal same as that of the bottom portion, is formed on a dielectric-based material (e.g., the two parts of the corresponding ILD 44, two parts of the corresponding CESL 43, see FIG. 27, or the two adjacent corresponding gate spacers 361, see FIG. 18). Silicon atom, if any, in a dielectric-based material, has a strong bonding with the oxygen atom, the nitrogen atom and/or other atoms therein, and thus bonding of the silicon atom with the oxygen atom is unlikely to be broken, and thus the nitrogen atom and/or other atoms are unlikely to diffuse into the metal of the lateral portion. As such, the lateral portion is unlikely to have silicon atoms therein, or the amount of silicon atoms is low in comparison with that of the bottom portion. A gaseous metal halide is found to have high etching selectivity to a material having a smaller amount of silicon atoms than to a material having a larger amount of silicon atoms, resulting in the gaseous metal halide having a higher etching selectivity to the lateral portion than to the bottom portion of the dipole metal layer 65.

Examples of the hydrogen halide that serve as the etchant are hydrogen fluoride (HF), hydrogen chloride (HCl), hydrogen bromide (HBr), hydrogen iodide (HI), or the likes, or combinations thereof. The hydrogen halide may have an etching selectivity to the lateral portion than to the bottom portion of about 3:1 to about 1:1.

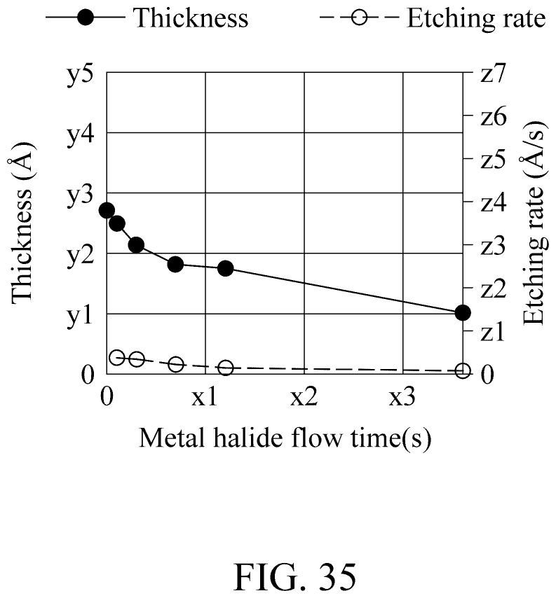

To examine such etching selectivity, three samples are prepared by depositing a metal selected from the possible materials of the dipole metal layer on films of a semiconductor-based material, a dielectric material of the ILD 44, and a dielectric material of the gate spacer 361, respectively. The three samples are subjected to etching by the etchant, which could be the gaseous metal halide and/or the gaseous hydrogen halide. In the examination, the gaseous metal halide is employed as the etchant, and variation in thickness and etching rate of the three samples are shown in FIGS. 35 to 37.

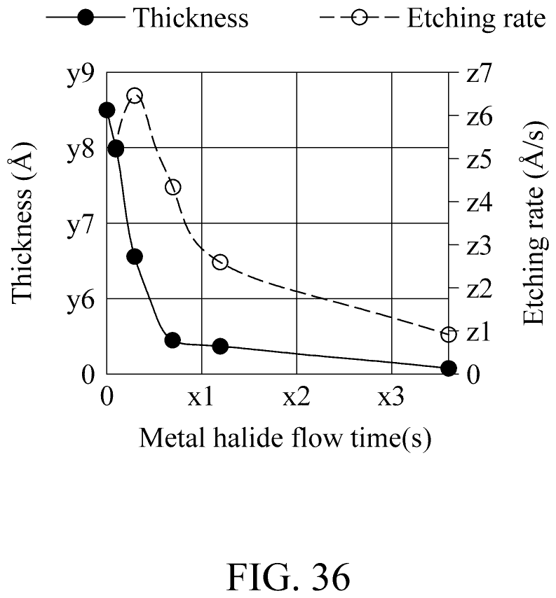

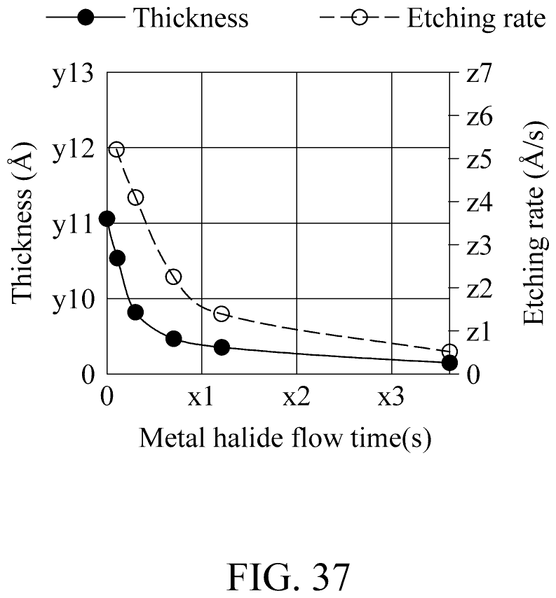

FIG. 35 shows the etching result of a material of the dipole metal layer that is formed on the semiconductor-based material (referred to as a dipole metal material on the semiconductor material hereinafter), wherein for the flow time of the metal halide is indicated by x1<x2<x3; the thickness of the dipole metal material is indicated by y1<y2<y3<y4<y5, and the etching rate of the dipole metal material is indicated by 21<22<<3<24<25<26<27. FIG. 36 shows the etching result of the dipole metal material that is formed on the material of the ILD 44 (referred to as the dipole metal material on the ILD material hereinafter), wherein the thickness of the dipole metal material is indicated by y6<y7<y8<y9. FIG. 37 shows the etching result of the dipole metal material that is formed on the material of the gate spacer 361 (referred to as the dipole metal material on the gate spacer material hereinafter), wherein the thickness of the dipole metal material is indicated by y10<y11<y12<y13. These results show that the thickness of the dipole metal material on the semiconductor material decreases at a much lower rate than the thickness of the dipole metal material on the ILD material and the thickness of the dipole metal material on the gate spacer material. In addition, the etching rate of the dipole metal material on the semiconductor material is much lower than the etching rate of the dipole metal material on the ILD material and the etching rate of the dipole metal material on the gate spacer material. In some cases, the etching selectivity of the dipole metal material on the semiconductor material to the dipole metal material on the ILD material may range from about 1:10 to about 1:17; and the etching selectivity of the dipole metal material on the semiconductor material to the dipole metal material on the gate spacer material may range from about 1:6 to about 1:13. From the above, it is clear that the gaseous metal halide has higher etching selectivity to a metal on a semiconductor-based material than to a metal on a dielectric-based material. As such, by forming the lateral portion and the bottom portion of the dipole metal layer 65 respectively on a dielectric-based material (e.g., silicon oxide, silicon nitride, silicon oxynitride, phosphosilicate glass, borophosphosilicate glass, spin-on glass, fluorosilicate glass, carbon-doped silicon oxide, xerogel, aerogel, parylene, divinylsiloxane-bis-benzocyclobutene-based dielectric material, polyimide, or other suitable dielectric materials) and a semiconductor-based material (e.g., silicon, silicon germanium or other suitable silicon-containing semiconductor materials), the lateral portion can be removed by the gaseous metal halide or the gaseous hydrogen halide without significantly reducing the bottom portion of the dipole metal layer 65.

The etching process may be performed at a temperature ranging from about 150° C. to about 500° C., and at a pressure ranging from about 1 Torr to about 9 Torr. A time period of the etching process may range from about 1 second to about 200 second. In some embodiments, the gaseous metal halide is introduced at a flow rate ranging from about 2 sccm to about 100 sccm, at a partial pressure ranging from about 0.001 Torr to about 0.6 Torr. A carrier gas, such as nitrogen gas (N₂), helium gas (He), neon gas (Ne), argon gas (Ar), other suitable gases, or combinations thereof, may also be used. Such etching conditions ensure complete removal of the lateral portion without etching too much of the bottom portion. Other suitable parameters and/or reagent for performing the etching process are within the contemplated scope of the present disclosure. In some embodiments, the etching process is performed in absence of plasma application.

After performing the soaking process, or also known as the etching process, as shown in FIG. 33, the lateral portion is removed to expose the two parts of the corresponding ILD 44, the two parts of the corresponding CESL 43, and the two corresponding gate spacers 361 (see FIG. 18), while the bottom portion of the dipole metal layer 65 remains and covers the bottom corresponding source/drain portion 42. The remaining bottom portion may have a thickness ranging from about 0.5 nm to about 4.8 nm.

Referring to FIG. 34, the first metal silicide layer 66 is formed along the sidewall and the bottom wall of the first trench 611 over the bottom portion of the dipole metal layer 65. Possible materials for the first metal silicide layer 66 are similar to those of the metal silicide layers 660, and thus details thereof are omitted for the sake of brevity.

Please note that the soaking process (shown in FIG. 33) and the process of forming the first metal silicide layer 66 (shown in FIG. 34) are performed in-situ. That is, after the soaking process, it is not necessary to switch to a different chamber and can directly forming the metal silicide layer 66 using the same chamber.

In some embodiments, the first metal silicide layer 66 is formed using the metal halide, which is employed as the etchant in the aforementioned soaking (etching) process, as a precursor. That is, the metal halide is used as the etchant in removing the lateral portion of the dipole metal layer 65, and also as the precursor for forming the first metal silicide layer 66. The first metal silicide layer 66 has a lower portion and a surrounding portion that extend upwardly from a periphery of the lower portion. In formation of the first metal silicide layer 66 in the n-type device, a metal layer is formed along an inner surface of the first trench 611 (e.g., along the two parts of the corresponding ILD 44, the two parts of the corresponding CESL 43 (see FIG. 18), the two corresponding gate spacers 361 (see FIG. 18) and the bottom corresponding source/drain portion 42), and the silicon atoms in the bottom corresponding source/drain portion 42 diffuse to and react with the metal layer adjacent to the bottom corresponding source/drain portion 42, while the silicon atoms in the two parts of the corresponding ILD 44, the two parts of the corresponding CESL 43, and the two corresponding gate spacers 361 are less likely to diffuse, thereby forming the first metal silicide layer 66 having the lower portion and the surrounding portion that has a silicon concentration lower than a silicon concentration of the lower portion. Such reaction may be represented by the chemical reaction:

NYₐ+e/2H₂+Q*→NYₐ₋ₑ+eHY+Q

NYₐ₋ₑ+dSi+(a−e)/2H₂→NSi_{d}+(a−e)HY

where N represents a metal atom of the metal halide,
Y represents a halogen atom of the metal halide,
Q represents a gas flowing though the chamber, such as argon,
Q* represents a plasma of the gas flowing through the chamber,
a is in a range of about 2 to about 6,
d is in a range of about 0.6 to about 2, and
e is 1 or 2

In some embodiments, the first metal silicide layer 66 is formed by depositing a metal layer using a CVD, PECVD, or other suitable processes, followed by reacting with silicon atoms from the source/drain portion 42. In addition, the metal halide-based precursor (e.g., a fluoride-based precursor, a chloride-based precursor, a bromide-based precursor, or iodide-based precursor) is used for forming etching the lateral portion of the dipole metal layer 65 and for forming the first metal silicide layer 66.

As such, in the n-type device, the lower portion of the first metal silicide layer 66 is mainly metal silicide and includes silicon from the corresponding source/drain portion 42. In addition, a concentration of silicon in the surrounding portion of the first metal silicide layer 66 is relatively small, and thus the surrounding portion is substantially made of metal.

In some embodiments, the first metal silicide layer 66 is formed using a CVD process, or a PECVD process, but are not limited thereto. The CVD/PECVD process may be performed at a temperature ranging from about 150° C. to about 500° C., and at a pressure ranging from about 1 Torr to about 9 Torr. The RF power may range from about 100 W to about 1000 W. The precursor, i.e., metal halide, may have an ampoule temperature ranging from about 25° C. to about 220° C., and may be introduced into the chamber at a flow rate ranging from about 1 sccm to about 100 sccm. Hydrogen may be introduced at a flow rate ranging from about 10 sccm to about 4000 sccm. The carrier gas may be introduced at a flow rate ranging from about 1000 sccm to about 3000 sccm. Other suitable processes and/or parameters for forming the first metal silicide layer 66 are within the contemplated scope of the present disclosure.

As such, the first metal silicide layer 66 is obtained as shown in FIG. 34. Referring backing to FIG. 28, the first metal silicide layer 66 is formed merely in the first trench 611 at the n-type region 14, but not in the second trench 612 at the p-type region 15.

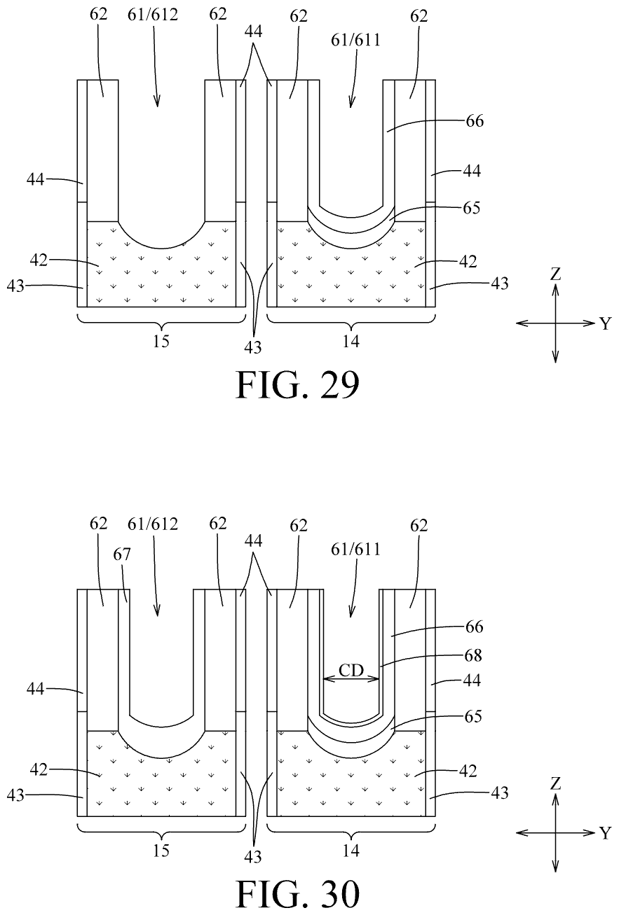

Referring to FIG. 22 and the example illustrated in FIG. 29, the method 1100 proceeds to step 1106, where the hard mask 63 (see FIG. 28) in the second trench 612 is removed. Any suitable processes known in the art may be freely adopted.

Referring to FIG. 22 and the example illustrated in FIG. 30, the method 1100 proceeds to step 1107, where a second metal silicide layer 67 and a third metal silicide layer 68 are respectively formed in the second trench 612 and the first trench 611.

The process of forming the second and third metal silicide layers 67, 68 is similar to the process of forming the first metal silicide layer 66, and thus details thereof are omitted for the sake of brevity. The second and third metal silicide layers 67, 68 may be made of a material that is the same or different from the material of the first metal silicide layer 66.

After step 1107, the second metal silicide layer 67 is formed in the second trench 612 at the p-type region 15, and the third metal silicide layer 68 is formed in the first trench 611 along the first metal silicide layer 66. Similar to the first metal silicide layer 66, each of the second metal silicide layer 67 and the third metal silicide layers 68 has a lower portion and a surrounding portion, the lower portion is made of metal silicide and formed on the bottom corresponding source/drain portion 42, and the surrounding portion is substantially made of metal and extends upwardly from a periphery of the lower portion. The first and third metal silicide layers 66, 68 cooperatively form a first metal silicide feature in the first trench 611 on top of the bottom corresponding source/drain portion 42 at the n-type region 14. The second metal silicide layer 67 serves as a second metal silicide feature in the second trench 612 on top of the bottom corresponding source/drain portion 42 at the p-type region 15. When the material of the source/drain portions 42 at the n-type region 14 is different from the material of the source/drain portions 42 at the p-type region 15, the first metal silicide feature may be different from the second metal silicide feature. For example, one of the first and second metal silicide features may include metal silicide, and the other one of the first and second metal silicide features may include metal silicide germanium. In some embodiments, a thickness of the second metal silicide feature is smaller than a thickness of the first metal silicide feature. In certain embodiments, the first metal silicide feature has a thickness ranging from about 3 nm to about 8 nm. The thickness of the bottom portion of the dipole metal layer 65 will influence the formation of the first metal silicide feature. For example, when the bottom portion of the dipole metal layer 65 is relatively thin, the first metal silicide feature is able to be formed with a relatively large thickness; and when the bottom portion of the dipole metal layer 65 is relatively thick, a thickness of the first metal silicide feature is reduced accordingly. In some embodiments, the second metal silicide feature has a thickness ranging from about 4 nm to about 6 nm. After step 1107, the first trench 611 at this stage (see FIG. 30) has a critical dimension (CD) ranging from about 6 nm to about 20 nm for forming the first metal contact 691 (see FIG. 31).

Referring to FIG. 22 and the example illustrated in FIG. 31, the method 1100 proceeds to step 1108, where a first metal contact 691 and a second metal contact 692 are formed respectively in the first and second trenches 611, 612.

Step 1108 may first include forming a metal filling layer (not shown) over the first and second trenches 611, 612, followed by a CMP process to remove an excess amount of the metal filling layer. The metal filling layer may include a conductive material, such as copper, tungsten, cobalt, ruthenium, aluminum, palladium, nickel, platinum, a low resistivity metal constituent, or the like, or combinations thereof, but are not limited thereto. Other suitable materials for forming the metal filling layer are within the contemplated scope of the present disclosure. After step 1108, the first and second metal contacts 691, 692 are formed respectively in the n-type device and the p-type device.

The n-type device is formed on the n-type region 14. Referring to the n-type device shown in the right part of FIG. 31 with reference to FIG. 21, the source/drain portion 42 in the n-type device serves as a first source/drain portion, the ILD 44 and the CESL 43 in the n-type device serve as a first dielectric feature, and the bottom portion of the dipole metal layer 65 serves as a dipole metal feature. The first dielectric feature 44, 43 is disposed on the first source/drain portion 42. The first metal contact 691 or 69 is formed to penetrate the first dielectric feature 44, 43 (see FIG. 21) so that the first dielectric feature 44, 43 is formed into two parts. The dipole metal feature 65 is disposed between the first metal contact 691 and the first source/drain portion 42. The first metal silicide feature 66, 68 is disposed around the first metal contact 691. In addition, the first metal silicide feature 66, 68 has a vertical portion and a first horizontal portion. The vertical portion is sandwiched between the first metal contact 691 and the first dielectric feature 44, 43. The first horizontal portion is sandwiched between the first metal contact 691 and the dipole metal feature 65.

The p-type device is formed on the p-type region 15. Referring to the p-type device shown in the left part of FIG. 31 with reference to FIG. 21, the source/drain portion 42 in the p-type device serves as a second source/drain portion, and the ILD 44 and the CESL 43 in the p-type device serve as a second dielectric feature. The second dielectric feature 44, 43 is disposed on the second source/drain portion 42. The second metal contact 692 or 69 is formed to penetrate the second dielectric feature 44, 43 (see also FIG. 21) so that the second dielectric feature 44, 43 is formed into two parts. The second metal silicide feature 67 is disposed around the second metal contact 692, and has a second vertical portion and a second horizontal portion. The second vertical portion is sandwiched between the second metal contact 692 and the second dielectric feature 44, 43. The second horizontal portion is sandwiched between the second metal contact 692 and the second source/drain portion 42.

The embodiments of the present disclosure have the following advantageous features. By including an etching process to remove the lateral portion of the dipole metal layer 65, the first trench 611 may have a larger capacity to accommodate the first metal contact 691, which is conducive to reducing SBH of the n-type device and allowing the first metal contact 691 to have a low resistance. In addition, the etchant employed in the etching process can also serve as the precursor for forming the first metal silicide feature, so as to reduce undesired contamination sources. Moreover, the etching process and formation of the first metal silicide layer of the first metal silicide feature can be performed in an in-situ manner (performed in one single chamber).

In accordance with some embodiments of the present disclosure, a method for forming a semiconductor structure includes: forming a trench in a base structure; forming a dipole metal layer in the trench, the dipole metal layer having a lateral portion formed along a sidewall of the trench and a bottom portion formed along a bottom wall of the trench; removing the lateral portion of the dipole metal layer using an etchant including at least one of a metal halide and a hydrogen halide; after removal of the lateral portion of the dipole metal layer, forming a metal silicide layer over the bottom portion of the dipole metal layer using a precursor including the metal halide; and forming a metal contact in the trench.

In accordance with some embodiments of the present disclosure, the etchant has a higher etching selectivity to the lateral portion than to the bottom portion.

In accordance with some embodiments of the present disclosure, the metal halide includes a nickel halide, platinum halide, palladium halide, cobalt halide, a titanium halide, erbium halide, zirconium halide, hafnium halide, ruthenium halide, or combinations thereof, and the metal silicide layer includes one of nickel silicide, platinum silicide, palladium silicide, cobalt silicide, titanium silicide, erbium silicide, zirconium silicide, hafnium silicide, ruthenium silicide, and combinations thereof.

In accordance with some embodiments of the present disclosure, the metal halide includes one of nickel fluoride, nickel dichloride, nickel bromide, nickel iodide, platinum difluoride, platinum trifluoride, platinum tetrachloride, platinum dichloride, platinum bromide, platinum diiodide, platinum tetraiodide, palladium difluoride, palladium trifluoride, palladium tetrafluoride, palladium hexafluoride, palladium dichloride, palladium trichloride, palladium tetrachloride, palladium dibromide, palladium tetrabromide, palladium diiodide, palladium tetraiodide, cobalt difluoride, cobalt trifluoride, cobalt dichloride, cobalt trichloride, cobalt iodide, titanium trifluoride, titanium tetrafluoride, titanium dichloride, titanium trichloride, titanium tetrachloride, titanium dibromide, titanium tribromide, titanium tetrabromide, titanium diiodide, titanium tetraiodide, erbium difluoride, erbium trifluoride, erbium trichloride, erbium tribromide, erbium triiodide, zirconium dibromide, zirconium dichloride, zirconium difluoride, zirconium diiodide, zirconium tribromide, zirconium trichloride, zirconium trifluoride, zirconium triiodide, zirconium tetrabromide, zirconium tetrachloride, zirconium tetrafluoride, zirconium tetraiodide, hafnium triiodide, hafnium tetrabromide, hafnium tetrachloride, hafnium tetrafluoride, hafnium tetraiodide, ruthenium dichloride, ruthenium tribromide, ruthenium trichloride, ruthenium trifluoride, ruthenium triiodide, ruthenium tetrachloride, ruthenium tetrafluoride, and combinations thereof.

In accordance with some embodiments of the present disclosure, the at least one of the metal halide and the hydrogen halide is in a gas phase.

In accordance with some embodiments of the present disclosure, the base structure includes a dielectric material-based feature, a semiconductor material-based feature, and the trench, the sidewall of the trench being bordered by the dielectric material-based feature, the bottom wall of the trench being bordered by the semiconductor material-based feature.

In accordance with some embodiments of the present disclosure, the dielectric material-based feature includes one of silicon oxide, silicon nitride, silicon oxynitride, phosphosilicate glass, borophosphosilicate glass, spin-on glass, fluorosilicate glass, carbon-doped silicon oxide, xerogel, aerogel, parylene, divinylsiloxane-bis-benzocyclobutene-based dielectric material, polyimide, and combinations thereof.

In accordance with some embodiments of the present disclosure, the semiconductor material-based feature includes a silicon-containing semiconductor material.

In accordance with some embodiments of the present disclosure, the base structure is an n-type device.

In accordance with some embodiments of the present disclosure, a method for manufacturing a semiconductor structure includes: forming a channel portion on a substrate; forming source/drain portions so that the channel portion is disposed between the source/drain portions; forming dielectric features over the source/drain portions, respectively; forming an active gate over the channel portion so that the dielectric features are at two opposite sides of the active gate, respectively; forming trenches respectively in the dielectric features so that the source/drain portions are respectively exposed from the trenches; forming dipole metal layers respectively in the trenches, the dipole metal layers each having a lateral portion formed along a sidewall of a respective one of the trenches, and a bottom portion formed along a bottom wall of the respective one of the trenches; performing a soaking process such that the lateral portion of each of the dipole metal layers is removed, and that the bottom portion of each of the dipole metal layers is at least partially remained; after performing the soaking process, forming metal silicide layers each of which is formed over the remaining bottom portion of a respective one of the dipole metal layers; and forming metal contacts respectively in the trenches.

In accordance with some embodiments of the present disclosure, the metal silicide layers are formed using a precursor that is employed as an etchant in the soaking process.

In accordance with some embodiments of the present disclosure, the precursor includes one of nickel fluoride, nickel dichloride, nickel bromide, nickel iodide, platinum difluoride, platinum trifluoride, platinum tetrachloride, platinum dichloride, platinum bromide, platinum diiodide, platinum tetraiodide, palladium difluoride, palladium trifluoride, palladium tetrafluoride, palladium hexafluoride, palladium dichloride, palladium trichloride, palladium tetrachloride, palladium dibromide, palladium tetrabromide, palladium diiodide, palladium tetraiodide, cobalt difluoride, cobalt trifluoride, cobalt dichloride, cobalt trichloride, cobalt iodide, titanium trifluoride, titanium tetrafluoride, titanium dichloride, titanium trichloride, titanium tetrachloride, titanium dibromide, titanium tribromide, titanium tetrabromide, titanium diiodide, titanium tetraiodide, erbium difluoride, erbium trifluoride, erbium trichloride, erbium tribromide, erbium triiodide, zirconium dibromide, zirconium dichloride, zirconium difluoride, zirconium diiodide, zirconium tribromide, zirconium trichloride, zirconium trifluoride, zirconium triiodide, zirconium tetrabromide, zirconium tetrachloride, zirconium tetrafluoride, zirconium tetraiodide, hafnium triiodide, hafnium tetrabromide, hafnium tetrachloride, hafnium tetrafluoride, hafnium tetraiodide, ruthenium dichloride, ruthenium tribromide, ruthenium trichloride, ruthenium trifluoride, ruthenium triiodide, ruthenium tetrachloride, ruthenium tetrafluoride, and combinations thereof, and the metal silicide layers each includes one of nickel silicide, platinum silicide, palladium silicide, cobalt silicide, titanium silicide, erbium silicide, zirconium silicide, hafnium silicide, ruthenium silicide, and combinations thereof.

In accordance with some embodiments of the present disclosure, for each of the dipole metal layers, the lateral portion is formed on a respective one of the dielectric features, and the bottom portion is formed on a respective one of the source/drain portions.

In accordance with some embodiments of the present disclosure, an etchant employed in the soaking process has a higher selectivity to the lateral portion than to the bottom portion, such that the lateral portion is removed and the bottom portion is at least partially remained.

In accordance with some embodiments of the present disclosure, the channel portion includes channels, and the active gate is formed around each of the channels.

In accordance with some embodiments of the present disclosure, the dipole metal layers each includes one of zirconium, hafnium, antimony, cerium, scandium, yttrium, ytterbium, erbium, dysprosium, lanthanum, gadolinium, aluminum, tungsten, titanium, zinc, beryllium, molybdenum, nickel, ruthenium, iridium, palladium, platinum, niobium, tungsten, cobalt, chromium, osmium, rhenium, rhodium, iron, manganese, vanadium, tantalum, and combinations thereof.

In accordance with some embodiments of the present disclosure, the method further includes forming spacer layers each of which is formed on the sidewall of the respective one of the trenches, prior to forming dipole metal layers.

In accordance with some embodiments of the present disclosure, the semiconductor structure is an n-type device.

In accordance with some embodiments of the present disclosure, a semiconductor includes a substrate having an n-type region and a p-type region, an n-type device formed at the n-type region; and a p-type device formed at the p-type region. The n-type device includes a first source/drain portion, a first dielectric feature disposed on the first source/drain portion, a first metal contact penetrating the first dielectric feature; a dipole metal feature disposed between the first metal contact and the first source/drain portion; and a first metal silicide feature disposed around the first metal contact. The first metal silicide feature has a first vertical portion that is sandwiched between the first metal contact and the first dielectric feature, and a first horizontal portion that is sandwiched between the first metal contact and the dipole metal feature. The p-type device includes a second source/drain portion, a second dielectric feature disposed on the second source/drain portion, a second metal contact penetrating the second dielectric feature, and a second metal silicide feature disposed around the second metal contact. The second metal silicide feature has a second vertical portion that is sandwiched between the second metal contact and the second dielectric feature, and a second horizontal portion that is sandwiched between the second metal contact and the second source/drain portion.

In accordance with some embodiments of the present disclosure, a thickness of the second metal silicide feature is smaller than a thickness of the first metal silicide feature.

The foregoing outlines features of several embodiments so that those skilled in the art may better understand the aspects of the present disclosure. Those skilled in the art should appreciate that they may readily use the present disclosure as a basis for designing or modifying other processes or structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A method for forming a semiconductor structure, comprising:
forming a trench in a base structure;
forming a dipole metal layer in the trench, the dipole metal layer having a lateral portion formed along a sidewall of the trench and a bottom portion formed along a bottom wall of the trench;
removing the lateral portion of the dipole metal layer using an etchant including at least one of a metal halide and a hydrogen halide;
after removal of the lateral portion of the dipole metal layer, forming a metal silicide layer over the bottom portion of the dipole metal layer using a precursor including the metal halide; and
forming a metal contact in the trench.

2. The method according to claim 1, wherein the etchant has a higher etching selectivity to the lateral portion than to the bottom portion.

3. The method according to claim 1, wherein
the metal halide includes a nickel halide, platinum halide, palladium halide, cobalt halide, a titanium halide, erbium halide, zirconium halide, hafnium halide, ruthenium halide, or combinations thereof, and
the metal silicide layer includes one of nickel silicide, platinum silicide, palladium silicide, cobalt silicide, titanium silicide, erbium silicide, zirconium silicide, hafnium silicide, ruthenium silicide, and combinations thereof.

4. The method according to claim 1, wherein the metal halide includes one of nickel fluoride, nickel dichloride, nickel bromide, nickel iodide, platinum difluoride, platinum trifluoride, platinum tetrachloride, platinum dichloride, platinum bromide, platinum diiodide, platinum tetraiodide, palladium difluoride, palladium trifluoride, palladium tetrafluoride, palladium hexafluoride, palladium dichloride, palladium trichloride, palladium tetrachloride, palladium dibromide, palladium tetrabromide, palladium diiodide, palladium tetraiodide, cobalt difluoride, cobalt trifluoride, cobalt dichloride, cobalt trichloride, cobalt iodide, titanium trifluoride, titanium tetrafluoride, titanium dichloride, titanium trichloride, titanium tetrachloride, titanium dibromide, titanium tribromide, titanium tetrabromide, titanium diiodide, titanium tetraiodide, erbium difluoride, erbium trifluoride, erbium trichloride, erbium tribromide, erbium triiodide, zirconium dibromide, zirconium dichloride, zirconium difluoride, zirconium diiodide, zirconium tribromide, zirconium trichloride, zirconium trifluoride, zirconium triiodide, zirconium tetrabromide, zirconium tetrachloride, zirconium tetrafluoride, zirconium tetraiodide, hafnium triiodide, hafnium tetrabromide, hafnium tetrachloride, hafnium tetrafluoride, hafnium tetraiodide, ruthenium dichloride, ruthenium tribromide, ruthenium trichloride, ruthenium trifluoride, ruthenium triiodide, ruthenium tetrachloride, ruthenium tetrafluoride, and combinations thereof.

5. The method according to claim 1, wherein the at least one of the metal halide and the hydrogen halide is in a gas phase.

6. The method according to claim 1, wherein the base structure includes a dielectric material-based feature, a semiconductor material-based feature, and the trench, the sidewall of the trench being bordered by the dielectric material-based feature, the bottom wall of the trench being bordered by the semiconductor material-based feature.

7. The method according to claim 6, wherein the dielectric material-based feature includes one of silicon oxide, silicon nitride, silicon oxynitride, phosphosilicate glass, borophosphosilicate glass, spin-on glass, fluorosilicate glass, carbon-doped silicon oxide, xerogel, aerogel, parylene, divinylsiloxane-bis-benzocyclobutene-based dielectric material, polyimide, and combinations thereof.

8. The method according to claim 6, wherein the semiconductor material-based feature includes a silicon-containing semiconductor material.

9. The method according to claim 1, wherein the base structure is an n-type device.

10. A method for manufacturing a semiconductor structure, comprising:
forming a channel portion on a substrate;
forming source/drain portions so that the channel portion is disposed between the source/drain portions;
forming dielectric features over the source/drain portions, respectively;
forming an active gate over the channel portion so that the dielectric features are at two opposite sides of the active gate, respectively;
forming trenches respectively in the dielectric features so that the source/drain portions are respectively exposed from the trenches;
forming dipole metal layers respectively in the trenches, the dipole metal layers each having a lateral portion formed along a sidewall of a respective one of the trenches, and a bottom portion formed along a bottom wall of the respective one of the trenches;
performing a soaking process such that the lateral portion of each of the dipole metal layers is removed, and that the bottom portion of each of the dipole metal layers is at least partially remained;
after performing the soaking process, forming metal silicide layers each of which is formed over the remaining bottom portion of a respective one of the dipole metal layers; and
forming metal contacts respectively in the trenches.

11. The method according to claim 10, wherein the metal silicide layers are formed using a precursor that is employed as an etchant in the soaking process.

12. The method according to claim 11, wherein
the precursor includes one of nickel fluoride, nickel dichloride, nickel bromide, nickel iodide, platinum difluoride, platinum trifluoride, platinum tetrachloride, platinum dichloride, platinum bromide, platinum diiodide, platinum tetraiodide, palladium difluoride, palladium trifluoride, palladium tetrafluoride, palladium hexafluoride, palladium dichloride, palladium trichloride, palladium tetrachloride, palladium dibromide, palladium tetrabromide, palladium diiodide, palladium tetraiodide, cobalt difluoride, cobalt trifluoride, cobalt dichloride, cobalt trichloride, cobalt iodide, titanium trifluoride, titanium tetrafluoride, titanium dichloride, titanium trichloride, titanium tetrachloride, titanium dibromide, titanium tribromide, titanium tetrabromide, titanium diiodide, titanium tetraiodide, erbium difluoride, erbium trifluoride, erbium trichloride, erbium tribromide, erbium triiodide, zirconium dibromide, zirconium dichloride, zirconium difluoride, zirconium diiodide, zirconium tribromide, zirconium trichloride, zirconium trifluoride, zirconium triiodide, zirconium tetrabromide, zirconium tetrachloride, zirconium tetrafluoride, zirconium tetraiodide, hafnium triiodide, hafnium tetrabromide, hafnium tetrachloride, hafnium tetrafluoride, hafnium tetraiodide, ruthenium dichloride, ruthenium tribromide, ruthenium trichloride, ruthenium trifluoride, ruthenium triiodide, ruthenium tetrachloride, ruthenium tetrafluoride, and combinations thereof, and
the metal silicide layers each includes one of nickel silicide, platinum silicide, palladium silicide, cobalt silicide, titanium silicide, erbium silicide, zirconium silicide, hafnium silicide, ruthenium silicide, and combinations thereof.

13. The method according to claim 10, wherein for each of the dipole metal layers, the lateral portion is formed on a respective one of the dielectric features, and the bottom portion is formed on a respective one of the source/drain portions.

14. The method according to claim 13, wherein an etchant employed in the soaking process has a higher selectivity to the lateral portion than to the bottom portion, such that the lateral portion is removed and the bottom portion is at least partially remained.

15. The method according to claim 10, wherein the channel portion includes channels, and the active gate is formed around each of the channels.

16. The method according to claim 10, wherein the dipole metal layers each includes one of zirconium, hafnium, antimony, cerium, scandium, yttrium, ytterbium, erbium, dysprosium, lanthanum, gadolinium, aluminum, tungsten, titanium, zinc, beryllium, molybdenum, nickel, ruthenium, iridium, palladium, platinum, niobium, tungsten, cobalt, chromium, osmium, rhenium, rhodium, iron, manganese, vanadium, tantalum, and combinations thereof.

17. The method according to claim 10, further comprising forming spacer layers each of which is formed on the sidewall of the respective one of the trenches, prior to forming dipole metal layers.

18. The method according to claim 10, wherein the semiconductor structure is an n-type device.

19. A semiconductor structure, comprising:
a substrate having an n-type region and a p-type region;
an n-type device formed at the n-type region, and including:
a first source/drain portion;
a first dielectric feature disposed on the first source/drain portion;
a first metal contact penetrating the first dielectric feature;
a dipole metal feature disposed between the first metal contact and the first source/drain portion; and
a first metal silicide feature disposed around the first metal contact, the first metal silicide feature having a first vertical portion that is sandwiched between the first metal contact and the first dielectric feature, and a first horizontal portion that is sandwiched between the first metal contact and the dipole metal feature; and
a p-type device formed at the p-type region, and including:
a second source/drain portion;
a second dielectric feature disposed on the second source/drain portion;
a second metal contact penetrating the second dielectric feature; and
a second metal silicide feature disposed around the second metal contact, the second metal silicide feature having a second vertical portion that is sandwiched between the second metal contact and the second dielectric feature, and a second horizontal portion that is sandwiched between the second metal contact and the second source/drain portion.

20. The semiconductor structure according to claim 19, wherein a thickness of the second metal silicide feature is smaller than a thickness of the first metal silicide feature.
